(19) United States
(12) Patent Application Publication
(10) Pub. No.: US 2011/0241697 A1
(43) Pub. Date: Oct. 6, 2011

(54) INSULATION DIAGNOSIS METHOD, INSULATION DIAGNOSIS SYSTEM, AND ROTATING ELECTRIC MACHINE

(76) Inventors: Chie Omatsu, Mito-shi (JP); Koji Obata, Hitachi-shi (JP); Shuya Hagiwara, Mito-shi (JP)

(21) Appl. No.: 13/075,379

(22) Filed: Mar. 30, 2011

(30) Foreign Application Priority Data
Apr. 1, 2010 (JP) 2010-085119

(51) Int. Cl. G01R 31/02

(52) U.S. Cl. 324/551

(57) ABSTRACT

An insulation diagnosis method according to the present invention includes: measurement step through which a signal generated at a diagnosis target device is measured; detection step through which a frequency or a frequency band manifesting a maximum amplitude signal strength is detected from the signal having been measured through the measurement step; and identification step through which an insulation defect type pertaining to an insulation defect having occurred in the diagnosis target device is identified based upon the frequency or the frequency band manifesting the maximum amplitude signal strength having been detected through the detection step.

### INCORPORATION BY REFERENCE

The disclosure of the following priority application is herein incorporated by reference: Japanese Patent Application No. 2010-085119 filed Apr. 1, 2010.

### BACKGROUND OF THE INVENTION

1. Field of the Invention

The present invention relates to an insulation diagnosis method, an insulation diagnosis system and a rotating electric machine.

2. Description of Related Art

There is a partial-discharge diagnostic method through which a partial discharge occurring within a gas insulating apparatus is detected via a detector, frequency analysis is executed for the partial discharge signal and the specific insulation defect type to which the particular partial discharge belongs is estimated based upon a frequency spectrum in a range of several hundred megahertz to several gigahertz indicated in the analysis results, or based upon the voltage phase of the partial discharge that is synchronous with the frequency applied to the gas insulating apparatus (see Japanese Laid Open Patent Publication No. 2006-170815).

### SUMMARY OF THE INVENTION

However, there is an issue to be addressed if the gas insulating apparatus partial-discharge diagnostic method in the related art described above is to be applied to a rotating electric machine for insulation diagnosis in that since the high-frequency side signal component in the partial discharge signal tends to become attenuated readily and the noise signal strength in the surrounding environment is significant on the low-frequency side, types of insulation defects that are particularly problematic in the rotating electric machine, such as a wire-to-wire discharge defect, a void discharge defect and a surface discharge defect, cannot be accurately identified.

According to the 1st aspect of the present invention, an insulation diagnosis method comprises: a measurement step of measuring a signal generated at a diagnosis target device; a detection step of detecting a frequency or a frequency band manifesting a maximum amplitude signal strength is detected from the signal having been measured through the measurement step; and an identification step of identifying an insulation defect type pertaining to an insulation defect having occurred in the diagnosis target device based upon the frequency or the frequency band manifesting the maximum amplitude signal strength having been detected through the detection step.

According to the 2nd aspect of the present invention, in an insulation diagnosis method according to the 1st aspect, it is preferred that, in the detection step, a frequency spectrum of the signal having been measured through the measurement step is detected and a frequency manifesting a maximum amplitude signal strength on the frequency spectrum is detected.

According to the 3rd aspect of the present invention, in an insulation diagnosis method according to the 1st aspect, it is preferred that, in the detection step, the signal having been measured through the measurement step is filtered through a plurality of band pass filters bearing different frequency band characteristics and a frequency band manifesting a maximum amplitude signal strength is detected by comparing strengths of signals which have passed the plurality of band pass filters.

According to the 4th aspect of the present invention, in an insulation diagnosis method according to the 1st aspect, it is preferred that, in the measurement step, signals are measured via a plurality of sensors bearing different frequency band characteristics; and in the detection step, a frequency range corresponding to a signal indicating a maximum amplitude signal strength is detected by comparing strengths of the signals having been measured via the plurality of sensors through the measurement step.

According to the 5th aspect of the present invention, in an insulation diagnosis method according to the 1st aspect, it is preferred that, in the measurement step, signals generated from the diagnosis target device are measured via a plurality of sensors bearing same characteristics; and an estimation step is executed in order to estimate an insulation defect position based upon a strength ratio of strengths of the signals having been measured via the plurality of sensors bearing same characteristics.

According to the 6th aspect of the present invention, in an insulation diagnosis method according to the 5th aspect, it is preferred that the plurality of sensors comprise a fixed sensor assuming a fixed position relative to the diagnosis target device and a movable sensor assuming a variable position relative to the diagnosis target device; and in the estimation step, the insulation defect position is estimated based upon a strength ratio of strengths of signals measured via the fixed sensor and the movable sensor.

According to the 7th aspect of the present invention, in an insulation diagnosis method according to the 5th aspect, it is preferred that, in the measurement step, the strengths of the signals having been measured via the plurality of sensors bearing same characteristics are compared and a partial discharge signal attributable to an insulation defect and noise are separated from each other based upon comparison results.

According to the 8th aspect of the present invention, in an insulation diagnosis method according to the 1st aspect, it is preferred that, in the measurement step, a partial discharge signal attributable to an insulation defect is extracted by taking a difference between the signal having been measured and noise having been measured in advance.

According to the 9th aspect of the present invention, in an insulation diagnosis method according to the 1st aspect, it is preferred that, in the measurement step, signals generated from the measurement target device are measured via a first sensor and a second sensor that measure different types of signals and a signal detected simultaneously via the first sensor and the second sensor is extracted as a partial discharge signal attributable to an insulation defect.

According to the 10th aspect of the present invention, in an insulation diagnosis method according to the 1st aspect, it is preferred that, in the measurement step, a signal component in the signal having been measured, which exceeds a preselected threshold value, is extracted as a partial discharge signal attributable to an insulation defect.

According to the 11th aspect of the present invention, in an insulation diagnosis method according to the 1st aspect, it is preferred that, in the identification step, a wire-to-wire discharge defect, a void discharge defect or a surface discharge defect, occurring in a rotating electric machine designated as the diagnosis target device, is identified.

According to the 12th aspect of the present invention, in an insulation diagnosis method according to the 11th aspect, it is preferred that, in the identification step, an insulation defect having occurred is identified as the wire-to-wire discharge defect if the frequency manifesting the maximum amplitude signal strength is in a range of 50 through 70 MHz, as the void discharge defect if the frequency manifesting the maximum amplitude signal strength is in a range of 2 through 20 MHz and as the surface discharge defect if the frequency manifesting the maximum amplitude signal strength is in a range of 30 through 50 MHz.

According to the 13th aspect of the present invention, in an insulation diagnosis method according to the 11th aspect, it is preferred that, in the measurement step, a signal generated from the rotating electric machine is measured via a sensor installed at the rotating electric machine.

According to the 14th aspect of the present invention, a rotating electric machine for which insulation diagnosis is executed by adopting an insulation diagnosis method according to claim 1.

According to the 15th aspect of the present invention, an insulation diagnosis system, comprises: a detection unit that detects a frequency or a frequency range manifesting a maximum amplitude signal strength based upon a signal provided by a measuring device that measures a signal generated from an insulation diagnosis target device; and an identification unit that identifies an insulation defect type pertaining to an insulation defect having occurred in the diagnosis target device based upon the frequency or the frequency range manifesting the maximum amplitude signal strength having been detected by the detection unit.

According to the 16th aspect of the present invention, in an insulation diagnosis system according to the 15th aspect, it is preferred that the detection unit detects a frequency spectrum of the signal having been measured by the measuring device and detects a frequency manifesting a maximum amplitude signal strength on the frequency spectrum.

According to the 17th aspect of the present invention, in an insulation diagnosis system according to the 15th aspect, it is preferred that the detection unit filters the signal having been measured by the measuring device through a plurality of band pass filters bearing different frequency band characteristics and detects a frequency band manifesting a maximum amplitude signal strength.

According to the 18th aspect of the present invention, in an insulation diagnosis system according to the 15th aspect, it is preferred that the measuring device measures signals via a plurality of sensors bearing different frequency band characteristics; and the detection unit detects a frequency range corresponding to a signal indicating a maximum amplitude signal strength among the signals having been measured via the plurality of sensors.

### BRIEF DESCRIPTION OF THE DRAWINGS

FIG. 1 is a diagram showing the configuration of the insulation diagnosis system achieved in a first embodiment.

FIG. 2 shows in detail how sensors measure a partial discharge having occurred in the rotating electric machine.

FIGS. 3A through 3H are diagrams pertaining to the noise separation processing executed by the noise separator to separate a partial discharge signal from noise.

FIG. 4 indicates the signal strengths of the partial discharge signal and the noise relative to the distance from a front position at the partial discharge location.

FIGS. 5A and 5B illustrate how the frequency conversion processing is executed for a partial discharge signal.

FIGS. 6A through 6C shows partial discharge signal frequency spectrums, each corresponding to a specific insulation defect type.

FIG. 7 presents a flowchart of the processing executed based upon an insulation defect type identification program.

FIG. 8 presents a first display example for indicating the insulation defect type.

FIG. 9 presents a second display example for indicating the insulation defect type.

FIG. 10 presents a third display example for indicating the insulation defect type.

FIG. 11 presents a fourth display example for indicating the insulation defect type.

FIG. 12 presents an example of a system configuration that allows information indicating the insulation defect type, the insulation defect position and the like, obtained through insulation diagnosis, to be reported to the administrator of the rotating electric machine that is under insulation diagnosis.

FIG. 13 is a diagram showing the configuration of the insulation diagnosis system achieved in a second embodiment.

FIG. 14 shows in detail how sensors measure a partial discharge having occurred in the rotating electric machine.

FIG. 15 presents a flowchart of the processing executed based upon an insulation defect type identification program.

FIG. 16 shows in detail how sensors measure a partial discharge having occurred in the rotating electric machine achieved in a third embodiment.

FIGS. 17A through 17F are diagrams pertaining to the noise separation processing executed by the noise separator to separate a partial discharge signal from noise.

FIG. 18 shows in detail how sensors measure a partial discharge having occurred in the rotating electric machine achieved in a fourth embodiment.

FIGS. 19A and 19B are diagrams pertaining to the noise separation processing executed by the noise separator to separate a partial discharge signal from noise.

FIG. 20 shows in detail how a sensor measures a partial discharge having occurred in the rotating electric machine achieved in a fifth embodiment.

FIG. 21 is a diagram pertaining to the noise separation processing executed by the noise separator to separate a partial discharge signal from noise.

FIGS. 22A through 22D are diagrams pertaining to the noise separation processing executed by the noise separator achieved in a sixth embodiment to separate a partial discharge signal from noise.

FIG. 23 is a diagram showing the configuration of the insulation diagnosis system achieved in a seventh embodiment.

FIG. 24 shows in detail how a sensor measures a partial discharge having occurred in the rotating electric machine.

FIG. 25 presents a flowchart of the processing executed by the identifier based upon an insulation defect type identification program.

FIGS. 26A through 26D each show how the plurality of partial discharge signal acquisition sensors characterizing an eighth embodiment may be installed in a rotating electric machine.

FIG. 27 shows the configuration achieved in a ninth embodiment, which allows electromagnetic waves attributable to a partial discharge having occurred in a rotating electric machine driven by a power source, to be obtained by a fixed sensor and a movable sensor.

FIG. 28 indicates the signal strength ratio relative to the distance between the fixed sensor and the movable sensor.

### DESCRIPTION OF PREFERRED EMBODIMENTS

Embodiments of the present invention, achieved by adopting the insulation diagnosis method and the insulation diagnosis system according to the present invention in conjunction with rotating electric machines, are described below. It is to be noted that the present invention may also be adopted in conjunction with other standard electrical devices such as a gas-insulated device, as well as rotating electric machines.

Deterioration of insulating condition in a rotating electric machine, such as a wind-powered generator, a turbine generator, an automotive motor dynamo or a standard industrial motor generator, may be attributed to a wire-to-wire discharge occurring at a surface ranging between enameled wires, a void discharge occurring within a ground insulation between a slot internal coil and the core or a surface discharge occurring at a location between the coil end and the core. A wire-to-wire discharge occurs as a high voltage is applied between wires clad with an insulator such as enamel. An interlayer void discharge occurs in an air gap within an insulator such as a mica paper plate containing air gaps when a high voltage is applied to the insulator. A surface discharge occurs over a range equivalent to the creeping distance between a high voltage area and a grounding area both present on a line such as an enameled wire. While three different types of insulation defects are identified in the embodiments described below, a type of insulation defect other than the three listed herein may also be identified.

### First Embodiment

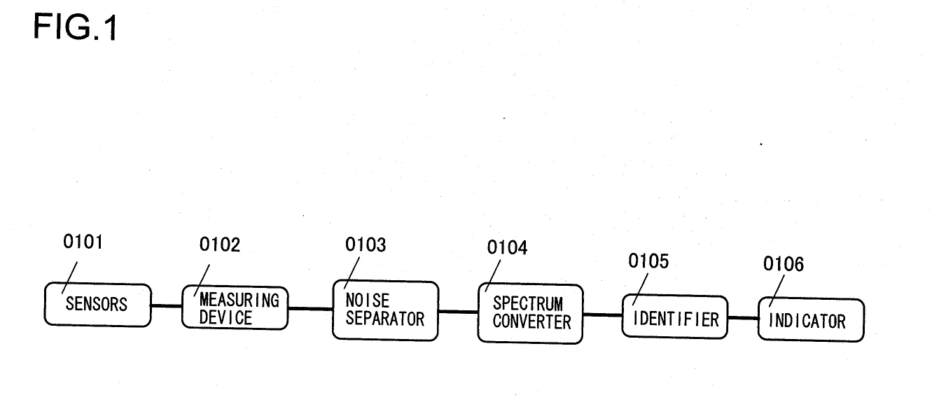

FIG. 1 shows the configuration of the insulation diagnosis system achieved in the first embodiment. The insulation diagnosis system comprises sensors 0101, a measuring device 0102, a noise separator 0103, a spectrum converter 0104, an identifier 0105, an indicator 0106 and the like. Via the sensors 0101, signals pertaining to a partial discharge occurring in an insulation defect area in a rotating electric machine as the insulation diagnosis target are obtained. Such a signal will contain noise occurring in an electric device installed around the rotating electric machine, e.g., an inverter power source used as the drive source for the rotating electric machine. It is to be noted that the quantity and the installation locations of the sensors 0101 will be described in detail later.

The measuring device 0102 measures the signals obtained via the sensors 0101 and the noise separator 0103 separates the signal component attributable to the partial discharge from the noise. The spectrum converter 0104 converts the partial discharge signal to a frequency and outputs a frequency spectrum. The identifier 0105 identifies the type of insulation defect based upon the frequency spectrum of the partial discharge signal, and the insulation defect type having been identified is indicated at the indicator 0106.

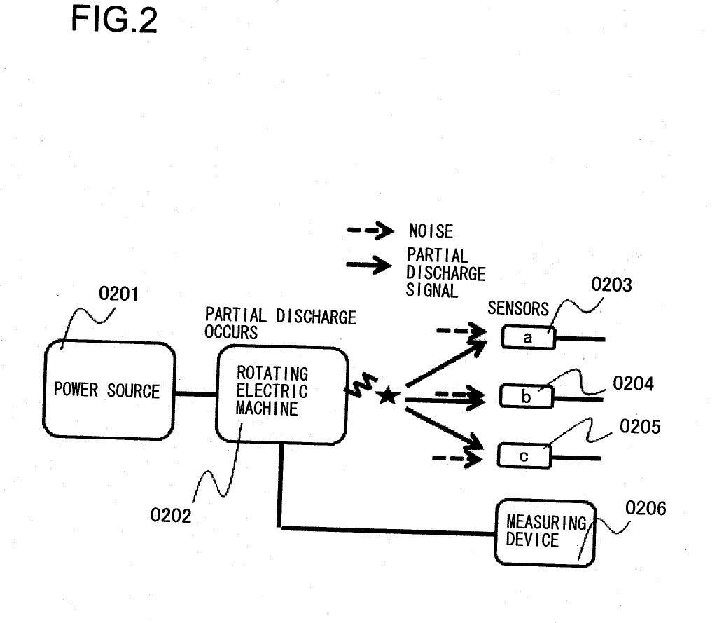

FIG. 2 shows in detail how the sensors measure a partial discharge having occurred in the rotating electric machine. A rotating electric machine 0202 as the insulation diagnosis target may be an AC motor generator driven by a power source 0201 such as an inverter or it may be a DC motor generator driven by a power source 0201 such as a converter. Signals pertaining to a partial discharge having occurred in the rotating electric machine 0202 are obtained via three sensors a0203, b0204 and c0205 installed in the rotating electric machine 0202 and a source voltage applied from the power source 0201 to the rotating electric machine 0202 is measured by a measuring device 0206.

The three sensors a0203, b0204 and c0205, installed at different locations within the rotating electric machine 0202, pick up electromagnetic waves attributable to a partial discharge having occurred in the rotating electric machine 0202 and its output is supplied to the measuring device 0102 shown in FIG. 1. It is to be noted that electromagnetic waves attributable to a partial discharge may be obtained via three sensors a0203, b0204 and c0205 also by installing them outside the rotating electric machine 0202. The three sensors a0203, b0204 and c0205 all assume identical frequency characteristics and cover a frequency range in a DC through 100 MHz range over which separation of a partial discharge signal attributable to a partial discharge occurring in the rotating electric machine 0202 from the noise, is considered to be difficult. FIG. 2 shows the noise (indicated by the dotted-line arrows in the figure) as well as partial discharge signal (indicated by the solid-line arrows in the figure) originating from the rotating electric machine 0202, with the three sensors a0203, b0204 and c0205 each picking up a partial discharge signal and the noise.

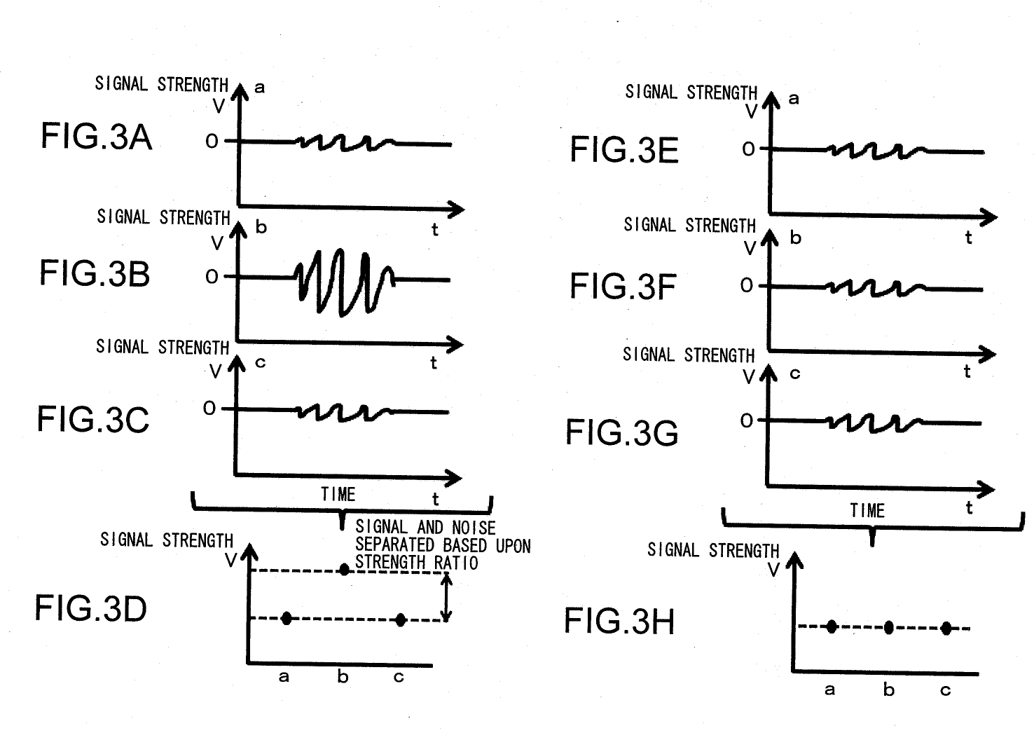

FIGS. 3A through 3H show how the noise separator 0103 (see FIG. 1) executes noise separation processing to separate the partial discharge signal from the noise. FIGS. 3A through 3C show the signal waveforms of signals respectively obtained at the sensors a0203, b0204 and c0205 and then measured by the measuring device 0102 in the event of a partial discharge, with the time t indicated along the horizontal axis and the signal strength V indicated along the vertical axis. In addition, FIGS. 3E through 3G show the signal waveforms of signals respectively obtained at the sensors a0203, b0204 and c0205 and then measured by the measuring device 0102 when there is no partial discharge occurring in the rotating electric machine. The partial discharge signals and the noise are separated by comparing the largest amplitude signal strengths indicated in the signal waveforms of the signals obtained at the sensors a0203, b0204 and c0205 installed at three locations.

FIG. 3D is a diagram obtained by plotting the maximum amplitude signal strength in the waveforms of signals obtained via the sensors a0203, b0204 and c0205 in the event of a partial discharge. The diagram in FIG. 3H, on the other hand, is obtained by plotting the maximum amplitude signal strengths in the waveforms of signals obtained via the sensors a0203, b0204 and c0205 in a partial discharge-free state. As FIGS. 3D and 3H clearly indicate, the partial discharge signal can be separated from the noise by comparing the signal indicating the highest maximum amplitude signal strength and the signal indicating the lowest maximum amplitude signal strength is the signal waveforms obtained via the three sensors a0203, b0204 and c0205 through the same period of time. In the example presented in FIG. 3D, the maximum amplitude signal strength detected via the sensor b0204 is higher than the maximum amplitude signal strengths detected via the other sensors a0203 and c0205, making it possible to determine that the signal obtained via the sensor b0204 is a partial discharge signal and that the signals obtained via the sensors a0203 and c0205 are noise. In the example presented in FIG. 3H, the signals obtained via the sensors a0203, b0204 and c0205 all indicate the same maximum amplitude signal strength levels and thus, the signals can be identified as noise.

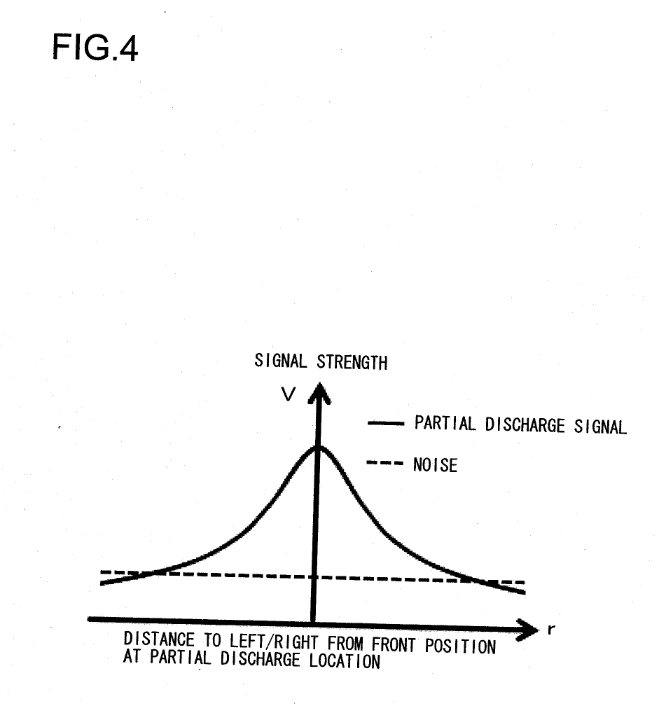

FIG. 4 indicates the signal strengths of the partial discharge signal (indicated by the solid line in the figure) and the noise (indicated by the dotted line in the figure) relative to the distance r from the front position at the partial discharge location. As FIG. 4 indicates, the signal strength V of the partial discharge signal becomes attenuated as the distance r from the position of the partial discharge signal source becomes larger, whereas the signal strength V of the noise remains constant regardless of the distance r from the position of the partial discharge signal source.

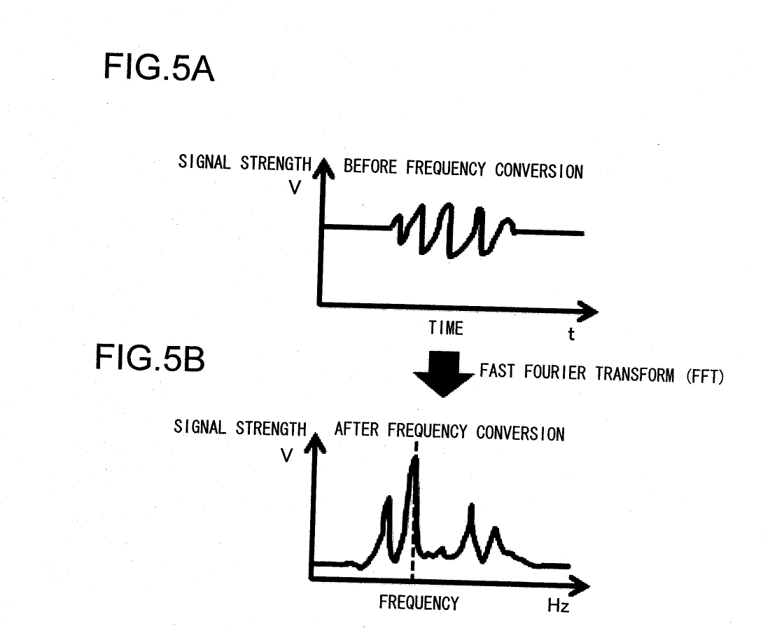

The partial discharge signal, having been separated through the noise separator 0103 (see FIG. 1) is provided to the spectrum converter 0104 (see FIG. 1), and analyzed in a frequency spectrum by a digital oscilloscope FFT or a spectrum analyzer constituting the spectrum converter 0104. FIGS. 5A and 5B illustrate the frequency conversion processing executed at the spectrum converter 0104, with FIG. 5A showing the partial discharge signal yet to undergo the frequency conversion and FIG. 5B showing the frequency spectrum resulting from the frequency conversion. The identifier 0105 (see FIG. 1) identifies the insulation defect type based upon the frequency spectrum of the partial discharge signal.

Through research conducted by the inventor of the present invention et al., it has been learned that signals resulting from partial discharges occurring in a rotating electric machine demonstrate the following characteristics. Namely, the results of a frequency analysis of partial discharge signals, pertaining to partial discharges occurring in a rotating electric machine, in the frequency range of DC through 100 MHz, over which a sufficient signal strength level is assured but noise separation is considered to be difficult in the related art, conducted by the inventor of the present invention et al. have revealed that the maximum amplitude signal strength is registered over a frequency range of 50 through 70 MHz in the frequency spectrum of a partial discharge signal attributable to a wire-to-wire discharge defect, that the maximum amplitude signal strength is registered over a frequency range of 2 through 20 MHz in the frequency spectrum of a partial discharge signal attributable to a void discharge defect, and that the maximum amplitude signal strength is registered over a frequency range of 30 through 50 MHz in the frequency spectrum of a partial discharge signal attributable to a surface discharge defect.

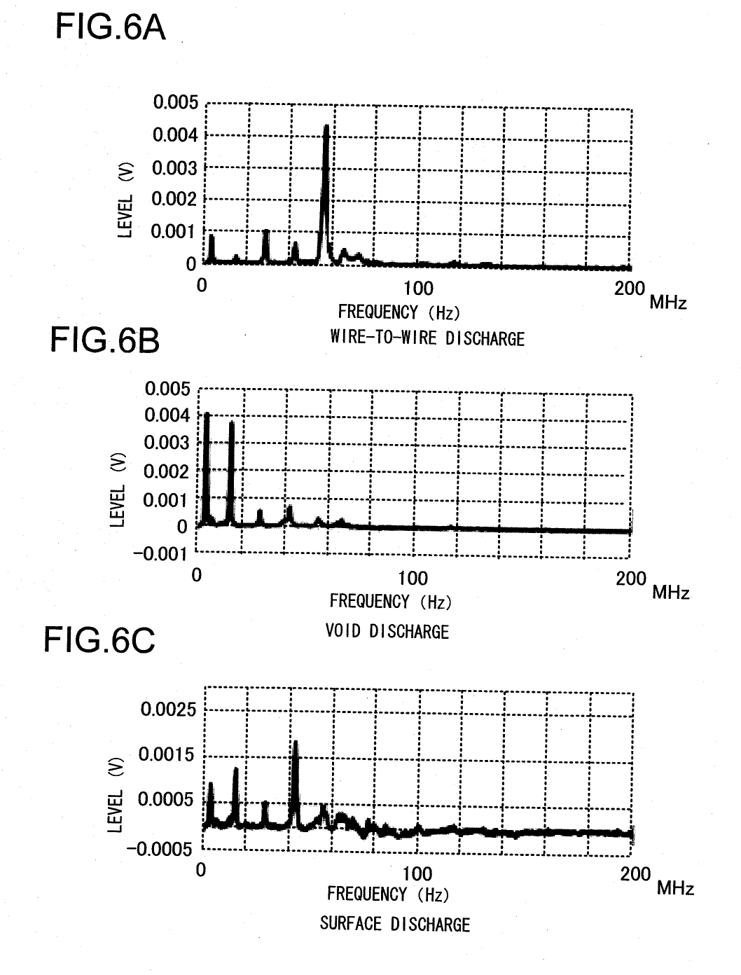

FIGS. 6A through 6C each present the frequency spectrum of a partial discharge signal corresponding to a specific type of insulation defect, with the frequency (Hz) indicated along the horizontal axis and the maximum amplitude signal strength level (V) indicated along the vertical axis. FIG. 6A shows the frequency spectrum of the partial discharge signal attributable to a wire-to-wire discharge, which registers the maximum amplitude signal strength over the 50 through 70 MHz frequency range. FIG. 6B shows the frequency spectrum of the partial discharge signal attributable to a void discharge, which registers the maximum amplitude signal strength over the 2 through 20 MHz frequency range. In addition, FIG. 6C shows the frequency spectrum of the partial discharge signal attributable to a surface discharge, which registers the maximum amplitude signal strength over the 30 through 50 MHz frequency range.

As described above, the frequency spectrums of the partial discharge signals attributable to the three primary types of insulation defect that occur in a rotating electric machine, i.e., the wire-to-wire discharge defect, the void discharge defect and the surface discharge defect, each register the maximum amplitude signal strength over a specific frequency range. This means that the type of each insulation defect that occurs in the rotating electric machine should be identified with accuracy by measuring the partial discharge signal generated from the insulation defect area, converting the measured partial discharge signal to a frequency spectrum and ascertaining the frequency range over which the maximum amplitude signal strength is registered.

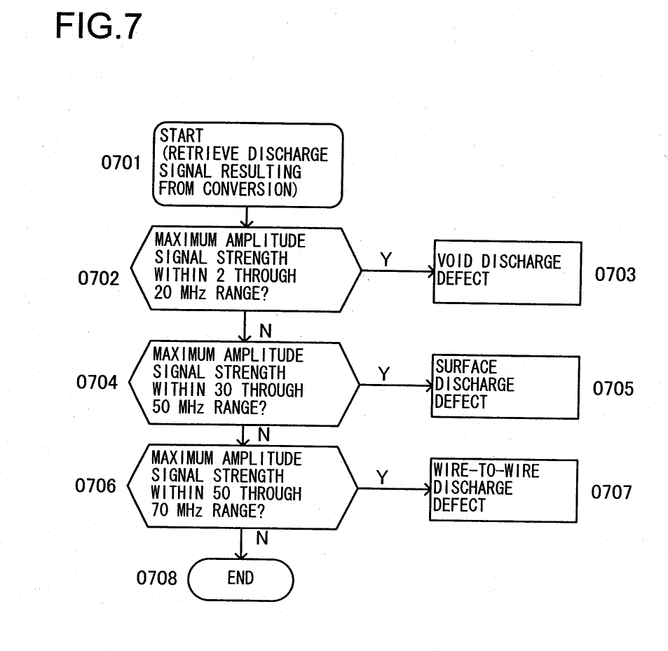

Based upon the research findings detailed above, the identifier 0105 executes the insulation defect type identification program shown in FIG. 7 so as to identify the type of a partial discharge that has occurred in the rotating electric machine 0202. In step 0701 in FIG. 7, the discharge signal having undergone the frequency spectrum conversion is retrieved. In the following step 0702, a decision is made as to whether or not the frequency corresponding to the maximum amplitude signal strength in the frequency spectrum is within the 2 through 20 MHz range and the operation proceeds to step 0703 if it is decided that the maximum amplitude signal strength is registered within the 2 through 20 MHz frequency range. In step 0703, the partial discharge having occurred in the rotating electric machine 0202 is identified as a partial discharge attributable to a void discharge defect.

If, on the other hand, it is decided in step 0702 that the frequency corresponding to the maximum amplitude signal strength is not within the 2 through 20 MHz range, the operation proceeds to step 0704, in which a decision is made as to whether or not the frequency corresponding to the maximum amplitude signal strength is within the 30 through 50 MHz range. The operation proceeds to step 0705 if it is decided that the maximum amplitude signal strength is registered within the 30 through 50 MHz range, and in step 0705, the partial discharge having occurred in the rotating electric machine 0202 is identified as a partial discharge attributable to a surface discharge defect.

If it is decided in step 0704 that the frequency corresponding to the maximum amplitude signal strength is not within the 30 through 50 MHz range, the operation proceeds to step 0706, in which a decision is made as to whether or not the frequency corresponding to the maximum amplitude signal strength is within the 50 through 70 MHz range. The operation proceeds to step 0707 if it is decided that the maximum amplitude signal strength is registered within the 50 through 70 MHz range, and in step 0707, the partial discharge having occurred in the rotating electric machine 0202 is identified as a partial discharge attributable to a wire-to-wire discharge defect.

If it is decided in step 0706 that the frequency corresponding to the maximum amplitude signal strength is not within the 50 through 70 MHz range, the cause of the partial discharge having occurred in the rotating electric machine 0202 cannot be determined to be a void discharge, a surface discharge or a wire-to-wire discharge and thus, the identification processing is terminated.

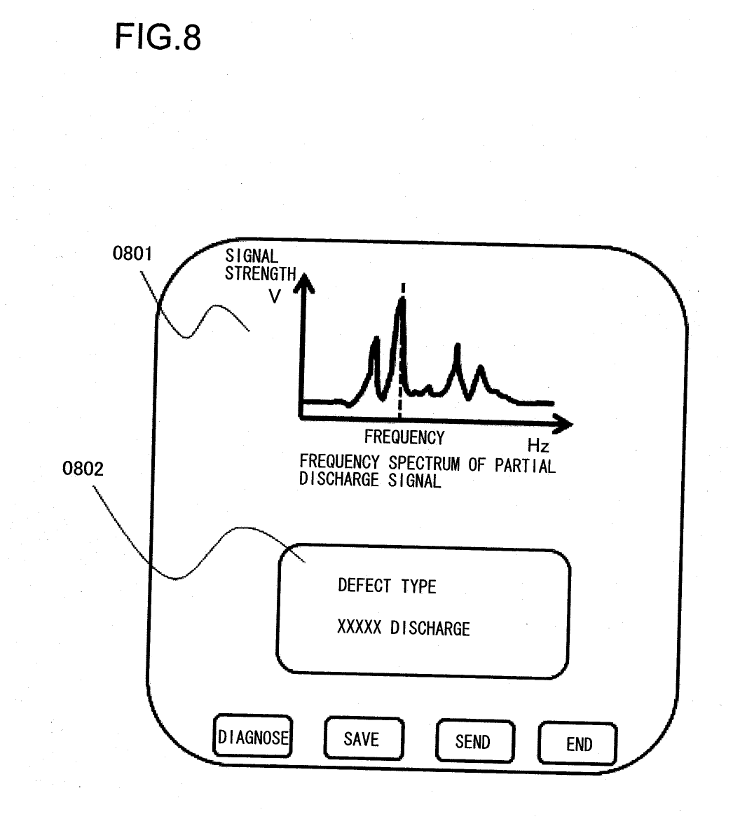

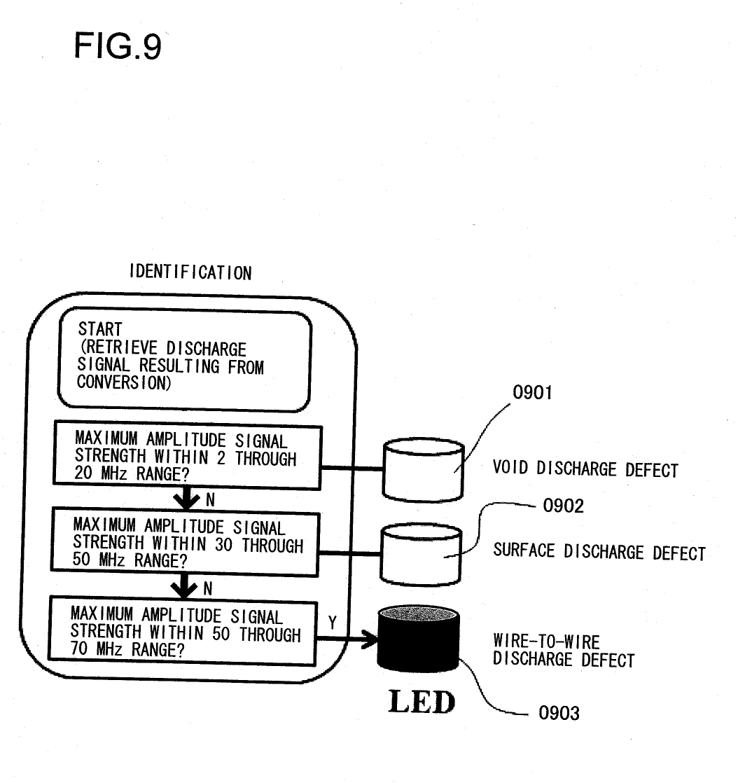

Upon identifying the insulation defect type, the insulation defect type having been identified is indicated at the indicator 0106 (see FIG. 1). FIG. 8 presents a first display example that may be adopted when indicating the insulation defect type. In the first display example, the frequency spectrum 0801 of the partial discharge signal, an insulation defect type 0802 and the like are displayed on the monitor of a personal computer. FIG. 9 presents a second option that may be adopted when indicating the insulation defect type. In the second display example, a void discharge defect indicator LED lamp 0901, a surface discharge defect indicator LED lamp 0902 and a wire-to-wire discharge defect indicator LED lamp 0903 are mounted. In the example presented in FIG. 9, the frequency corresponding to the maximum amplitude signal strength of the partial discharge signal is determined to be within the 50 through 70 MHz range and accordingly, the wire-to-wire discharge defect indicator LED lamp 0903 is lit.

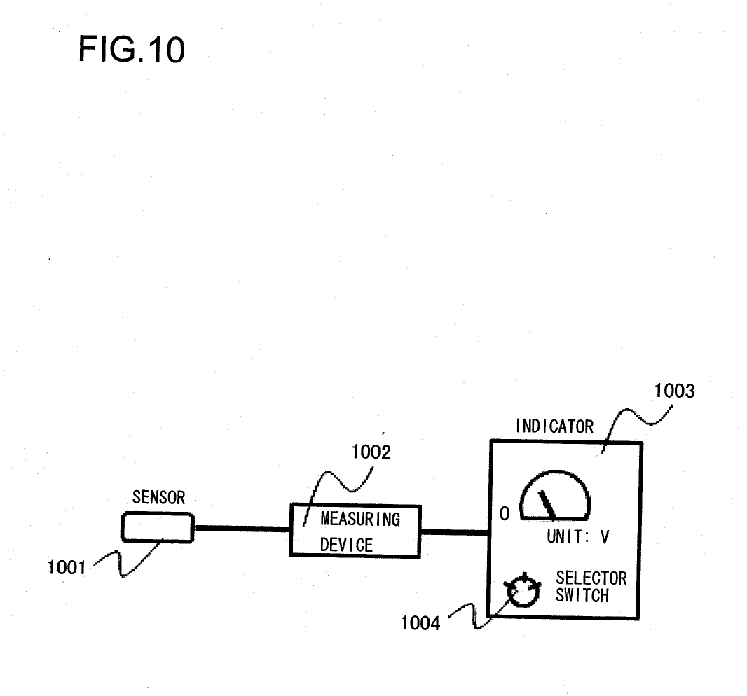

FIG. 10 presents a third display example that may be adopted when indicating the insulation defect type. In the third display example, the maximum amplitude signal strength of a partial discharge signal measured via a sensor 1001 and a measuring device 1002 is indicated in each frequency range which frequency range is switched by a selector switch 1004 at an indicator 1003. In this case, frequency ranges may be switched between, for instance, the 2 through 20 MHz band, the 30 through 50 MHz band and the 50 through 70 MHz band, and the insulation defect type may be identified by the frequency range which shows the highest maximum amplitude signal strength among the three frequency ranges.

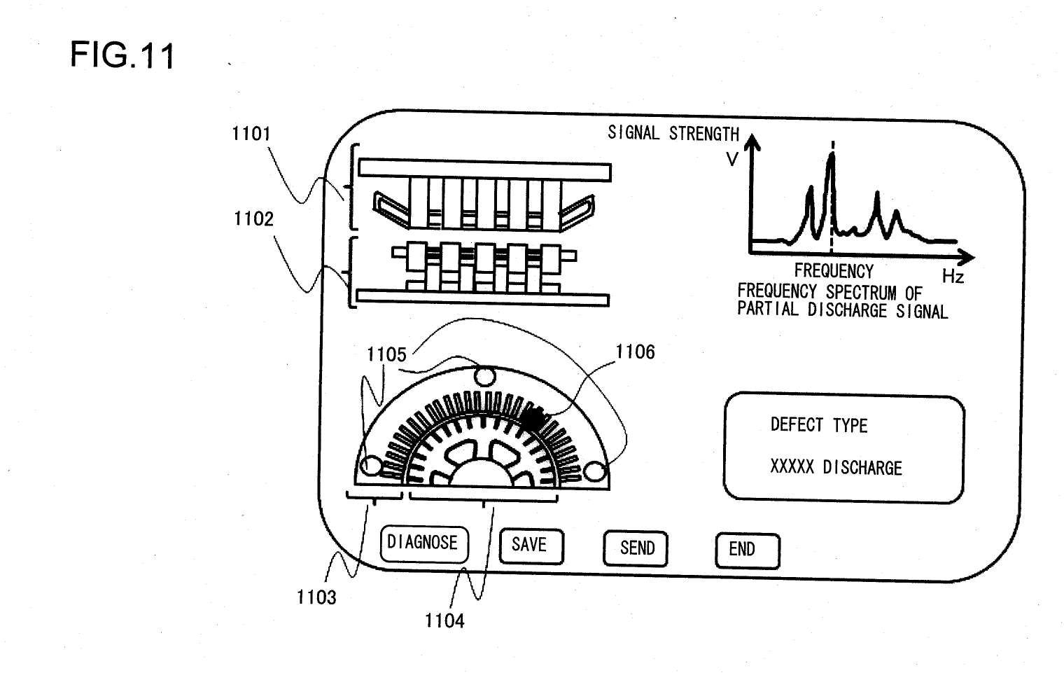

FIG. 11 presents a fourth display example that may be adopted when indicating the insulation defect type. In the fourth display example, the insulation defect position at which the partial discharge has occurred is indicated in addition to the display of the frequency spectrum of the partial discharge signal and the insulation defect type shown in FIG. 8. FIG. 11 shows a stator 1101 and a rotor 1102 of the rotating electric machine 0202 (see FIG. 2) displayed in a lateral sectional view in the upper left area of the display screen. It also shows the stator 1103 and the rotor 1104 of the rotating electric machine 0202 displayed in the longitudinal sectional view in the lower left area of the display screen together with the positions of three sensors 1105 mounted in the rotating electric machine 0202 and the insulation defect position 1106 where the partial discharge has occurred.

It is to be noted that as has been described in reference to FIG. 4, the signal strength of the partial discharge signal becomes attenuated as the distance from the insulation defect position at which the partial discharge has occurred increases. Accordingly, the insulation defect position 1106 can be estimated based upon the installation positions at which the three sensors 1105 are mounted and the signal strength of the detected partial discharge signal.

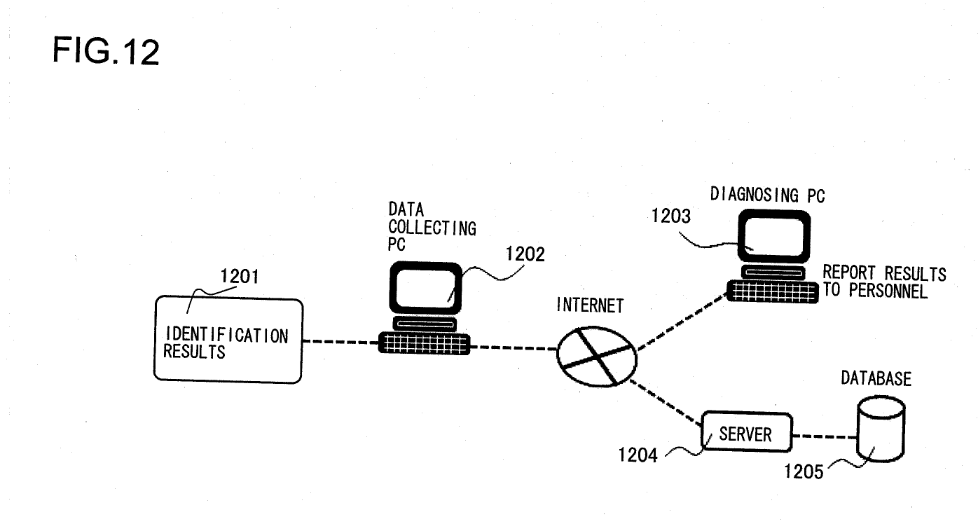

FIG. 12 presents an example of a system configuration that may be adopted in a system that allows information indicating the insulation defect type, the insulation defect position and the like ascertained through insulation diagnosis to be reported to the operator of a rotating electric machine as the insulation diagnosis target. FIG. 12 shows that identification results 1201 obtained through the insulation diagnosis are collected into a data collection PC 1202 and are then transmitted to a diagnosing PC 1203 via the Internet or the like. At the diagnosing PC 1203, a diagnosis is executed in a comprehensive manner based upon the latest information and a recorded diagnostic history so as to determine an at-risk area with deteriorating insulating conditions and reports the diagnosis results to the operator. It is to be noted that the data collected for diagnostic purposes are also transmitted to a server 1204 where the data are accumulated in a database 1205.

As described above, through the insulation diagnosis method achieved in the first embodiment by recognizing the partial discharge signal characteristics whereby the maximum amplitude strength is registered in a specific frequency range on the frequency spectrum of the partial discharge signal corresponding to a given type of insulation defect, the insulation defect type can be accurately identified based upon the analysis results indicating the specific frequency range to which the frequency corresponding to the maximum amplitude signal strength level belongs on the frequency spectrum of the partial discharge signal.

In addition, a plurality of sensors are installed for purposes of partial discharge signal acquisition and the partial discharge signal is separated from noise by comparing the signal strengths (maximum amplitude signal strengths) of the signals having been detected via the individual sensors. Thus, the type of insulation defect, e.g., the wire-to-wire discharge defect, the void discharge defect or the surface discharge defect, occurring in a rotating electric machine, for which accurate insulation diagnosis is considered difficult in the related art due to a significant noise signal strength in the surrounding environment on the low-frequency side, can be identified accurately.

Furthermore, since the partial discharge signal is obtained via a plurality of partial discharge signal acquisition sensors installed at various positions inside or outside the rotating electric machine and the insulation defect position is estimated based upon the installation positions at which the individual sensors are installed and the detected signal strengths, the insulation defect position at which the partial discharge has occurred can be identified in a reliable manner. Since this makes it possible to easily pinpoint the insulation defect area during rotating electric machine maintenance work, the time and cost required for repair work, in particular, can be reduced.

### Second Embodiment

While a partial discharge signal is obtained via three sensors bearing substantially same frequency bands in the first embodiment described above, a partial discharge signal is obtained in the second embodiment via three sensors with different frequency bands, each corresponding to a specific type of insulation defect among the primary insulation defects that occur in a rotating electric machine, i.e., the wire-to-wire discharge defect, the void discharge defect and the surface discharge defect described below.

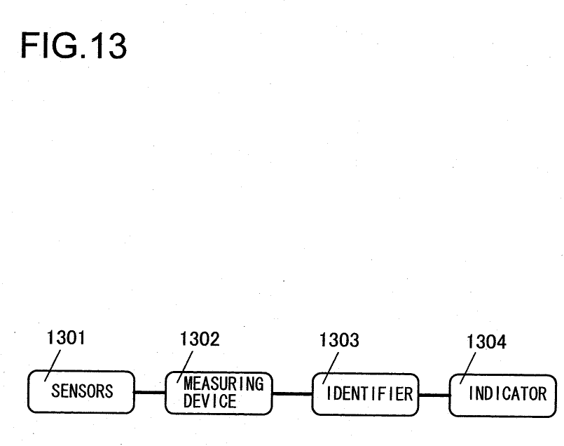

FIG. 13 shows the configuration of the insulation diagnosis system achieved in the second embodiment. The insulation diagnosis system comprises sensors 1301, a measuring device 1302, an identifier 1303, an indicator 1304 and the like. Via the sensors 1301, signals pertaining to a partial discharge occurring in an insulation defect area in a rotating electric machine as the insulation diagnosis target are obtained. Such a signal will contain noise occurring in an electric device installed around the rotating electric machine, e.g., an inverter power source used as the drive source for the rotating electric machine. It is to be noted that the quantity and the installation locations of the sensors 1301 will be described in detail later.

The measuring device 1302 measures the signals obtained via the sensors 1301, and the identifier 1303 identifies the insulation defect type based upon the signals measured in respective frequency ranges. The insulation defect type, having been identified, is indicated at the indicator 1304. It is to be noted that since the partial discharge signal is obtained via a sensor 1301 corresponding to the particular type of insulation defect having occurred in the rotating electric machine, the noise separator 0103 and the spectrum converter 0104 used in the first embodiment as shown in FIG. 1 are not required in the second embodiment.

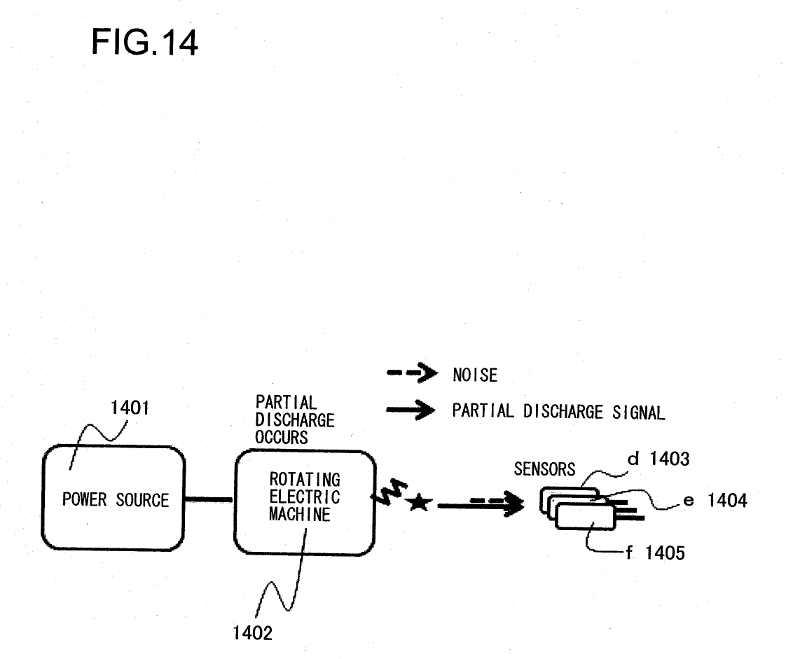

FIG. 14 shows in detail how the sensors measure a partial discharge having occurred in the rotating electric machine. A rotating electric machine 1402 as the insulation diagnosis target may be an AC motor generator driven by a power source 1401 such as an inverter or it may be a DC motor generator driven by a power source 1401 such as a converter. Signals pertaining to a partial discharge having occurred in the rotating electric machine 1402 are obtained via three sensors d1403, e1404 and f1405 installed in the rotating electric machine 1402 and the signals thus obtained are measured by the measuring device 1302 (see FIG. 13).

The three sensors d1403, e1404 and f1405, installed at one location within the rotating electric machine 1402, pick up electromagnetic waves attributable to a partial discharge having occurred in the rotating electric machine 1402, and its output is supplied to the measuring device 1302 (see FIG. 13). The three sensors d1403, e1404 and f1405 respectively bear characteristic frequency bands, 50 through 70 MHz frequency band, 2 through 20 MHz frequency band and 30 through 50 MHz frequency band, which, in turn, respectively correspond to the primary insulation defect types unique to the rotating electric machine 1402, i.e., the wire-to-wire discharge defect, the void discharge defect and the surface discharge defect. It is to be noted that noise (indicated by the dotted-line arrows in the figure) as well as the partial discharge signal (indicated by the solid-line arrows in the figure) originates from the rotating electric machine 1402, and that the three sensors d1403, e1404 and f1405 each pick up the partial discharge signal and the noise.

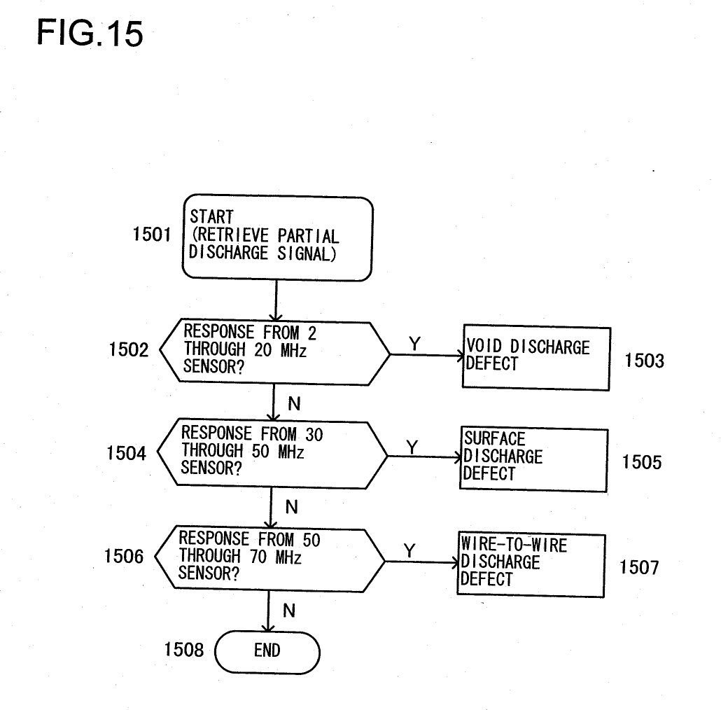

The identifier 1303 (see FIG. 13) executes the insulation defect type identification program shown in FIG. 15 so as to identify the type of a partial discharge having occurred in the rotating electric machine 1402. In step 1501, electromagnetic waves originating from the partial discharge location are detected via the three different types of sensors d1403, e1404 and f1405 installed at the same position and are then retrieved via the measuring device 1302.

Assuming that a partial discharge attributable to a wire-to-wire discharge has occurred in the rotating electric machine 1402, a signal with the maximum amplitude signal strength will be measured via the sensor d1403 corresponding to the partial discharge signal attributable to the wire-to-wire discharge defect with noise measured via the other sensors e1404 and f1405, as shown in FIG. 6A. If, on the other hand, a partial discharge attributable to a void discharge has occurred in the rotating electric machine 1402, a signal with the maximum amplitude signal strength will be measured via the sensor e1404 corresponding to the partial discharge signal attributable to the wire-to-wire discharge defect with noise measured via the other sensors d1403 and f1405, as shown in FIG. 6B.

If a partial discharge attributable to a surface discharge has occurred in the rotating electric machine 1402, a signal with the maximum amplitude signal strength will be measured via the sensor f1405 corresponding to the partial discharge signal attributable to the wire-to-wire discharge defect with noise measured via the other sensors d1403 and e1404, as shown in FIG. 6C. Based upon the signal strength ratios of the signals measured by the sensors d1403, e1404 and f1405, the partial discharge signal can be separated from the noise and the insulation defect type can be identified in correspondence to the frequency band of the sensor at which the maximum amplitude signal strength manifesting a signal strength level greater than that of the noise has been detected.

In step 1502, a decision is made as to whether or not the maximum amplitude signal strength has been detected at the sensor e1404 assuming the 2 through 20 MHz frequency range and if the maximum amplitude signal strength has been detected via the sensor e1404, the operation proceeds to step 1503 to identify the insulation defect type as a void discharge defect. If, on the other hand, the maximum amplitude signal strength has not been detected by the sensor e1404, the operation proceeds to step 1504 to make a decision as to whether or not the maximum amplitude signal strength has been detected via the sensor f1405 assuming the 30 through 50 MHz frequency range. If the maximum amplitude signal strength has been detected via the sensor f1405, the operation proceeds to step 1505 to identify the insulation defect type as the surface discharge defect.

If the maximum amplitude signal strength has not been detected by the sensor f1405, the operation proceeds to step 1506 to make a decision as to whether or not the maximum amplitude signal strength has been detected via the sensor d1403 assuming the 50 through 70 MHz frequency range. If the maximum amplitude signal strength has been detected via the sensor d1403, the operation proceeds to step 1507 to identify the insulation defect type as the wire-to-wire discharge defect. If the maximum amplitude signal strength has not been detected via the sensor d1403, the cause of the partial discharge having occurred in the rotating electric machine 1402 cannot be determined to be a void discharge, a surface discharge or a wire-to-wire discharge and thus, the identification processing is terminated.

Next, the insulation defect type having been identified by the identifier 1303 is indicated at the indicator 1304 (see FIG. 13). The insulation diagnosis results may be indicated at the indicator 1304 by adopting any of the display examples described in reference to the first embodiment.

In the insulation diagnosis method in the second embodiment, which eliminates the need for executing noise separation and frequency spectrum conversion and thus does not require the noise separator 0103 and the spectrum converter 0104 used in the insulation diagnosis method in the first embodiment, enables real-time identification of the insulation defect type in an insulation diagnosis system assuming an inexpensive and compact configuration.

### Third Embodiment

While a partial discharge signal is obtained via three sensors bearing substantially same frequency bands in the first embodiment described above, a partial discharge signal is obtained via two sensors bearing same frequency bands in the third embodiment described below. While the insulation diagnosis system achieved in the third embodiment includes two sensors instead of the three sensors installed in the insulation diagnosis system in the first embodiment shown in FIG. 1, it is otherwise similar to the insulation diagnosis system in the first embodiment. For this reason, an illustration and an explanation of the configuration of the insulation diagnosis system achieved in the third embodiment are omitted.

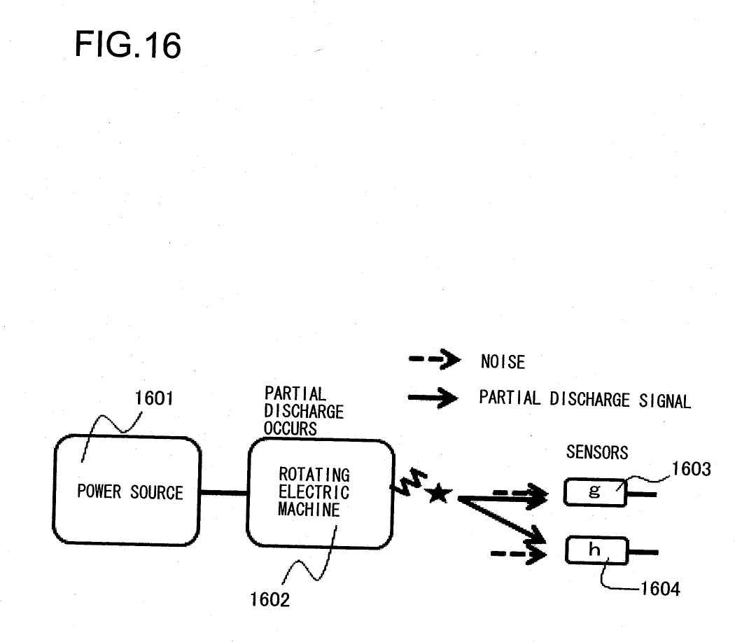

FIG. 16 shows in detail how the sensors measure a partial discharge having occurred in the rotating electric machine. A rotating electric machine 1602 as the insulation diagnosis target may be an AC motor generator driven by a power source 1601 such as an inverter or it may be a DC motor generator driven by a power source 1601 such as a converter. Signals pertaining to a partial discharge having occurred in the rotating electric machine 1602 are obtained via two sensors g1603 and h1604 installed in the rotating electric machine 1602.

The two sensors g1603 and h1604 installed at different locations within the rotating electric machine 1602, pick up electromagnetic waves attributable to a partial discharge having occurred in the rotating electric machine 1602 and its output is supplied to a measuring device (equivalent to the measuring device 0102 shown in FIG. 1). It is to be noted that electromagnetic waves attributable to a partial discharge may also be obtained via two sensors g1603 and h1604 installed outside the rotating electric machine 1602. The two sensors g1603 and h1604 bear same frequency characteristics and cover a frequency range in a DC through 100 MHz range over which separation of a partial discharge signal attributable to a partial discharge occurring in the rotating electric machine 1602 from the noise, is considered to be difficult. FIG. 16 shows the noise (indicated by the dotted-line arrows in the figure) as well as the partial discharge signals (indicated by the solid-line arrows in the figure) originating from the rotating electric machine 1602, with the two sensors g1603 and h1604 each picking up a partial discharge signal and the noise.

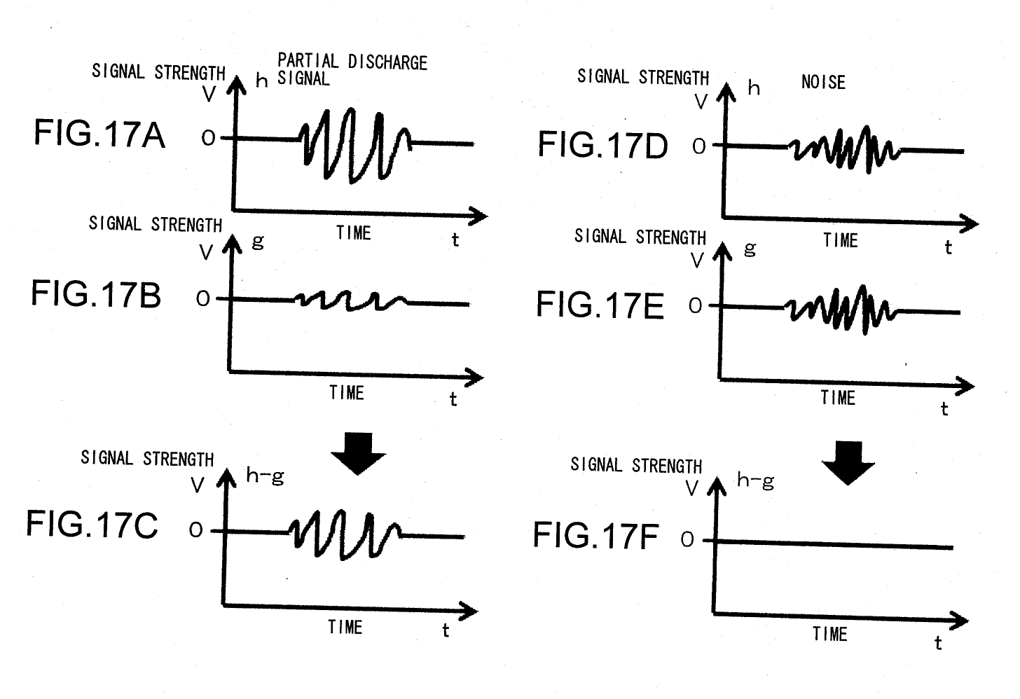

FIGS. 17A through 17F show how a noise separator (not shown, equivalent to the noise separator 0103 shown in FIG. 1) executes noise separation processing to separate the partial discharge signal from the noise. FIGS. 17A through 17F respectively show the signal waveforms of the signals respectively obtained at the sensors h1604 and g1603 and then measured by the measuring device (not shown, equivalent to the measuring device 0102 shown in FIG. 1), with the time t indicated along the horizontal axis and the signal strength V indicated along the vertical axis. In addition, FIGS. 17D and 17E show the signal waveforms of signals respectively obtained at the sensors h1604 and g1603 and then measured by the measuring device when there is no partial discharge occurring in the rotating electric machine.

The signal waveform shown in FIG. 17C represents the difference between the waveforms of the signals obtained via the two sensors g1603 and h1604, i.e., the difference between the signal waveform shown in FIG. 17A and the signal waveform shown in FIG. 17B. The signal waveform shown in FIG. 17F represents the difference between the signal waveforms shown in FIG. 17D and FIG. 17E pertaining to the signals obtained via the two sensors h1604 and g1603. It is to be noted that if the signal level of the sensor signals is not sufficiently high, the sensor signals should be amplified via an amplifier before taking their difference.

If a partial discharge signal has been obtained via either of the two sensors g1603 and h1604 and noise has been obtained via the other sensor, the difference between the waveforms of the signals having been obtained via the two sensors g1603 and h1604 will be represented by the signal waveform of the partial discharge signal, such as that shown in FIG. 17C. If, on the other hand, no partial discharge signal has been detected either via the sensor h1604 or the sensor g1603 but noise has been obtained via the two sensors g1603 and h1604, the difference between the waveforms of the signals having been obtained via the two sensors g1603 and h1604 will be represented by a substantially OV waveform, as shown in FIG. 17F.

The partial discharge signal, having been separated from the noise through the noise separator, is provided to a spectrum converter (not shown, equivalent to the spectrum converter 0104 shown in FIG. 1) where it undergoes frequency analysis. In addition, an identifier (not shown, equivalent to the identifier 0105 shown in FIG. 1) identifies the insulation defect type based upon the frequency spectrum of the partial discharge signal. The insulation defect type can be identified through a method similar to that shown in FIG. 7. Next, the insulation defect type having been identified is indicated at an indicator (not shown, equivalent to the indicator 0106 shown in FIG. 1). The insulation diagnosis results may be indicated at the indicator by adopting any of the display examples described in reference to the first embodiment.

As described above, the insulation diagnosis method in the third embodiment, which requires fewer partial discharge signal acquisition sensors, achieves an advantage in that an inexpensive and compact insulation diagnosis system is realized, in addition to the advantages of the first embodiment explained earlier.

### Fourth Embodiment

In the fourth embodiment described below, the insulation defect type is identified by measuring a partial discharge signal with a plurality of sensors which detect different types of signals, such as an electromagnetic wave sensor and an electric current sensor. Since the sensors are the only elements that differentiate the system configuration assumed in the fourth embodiment from the system configuration shown in FIG. 1, an illustration and an explanation of the system configuration of the insulation diagnosis system in the fourth embodiment are omitted.

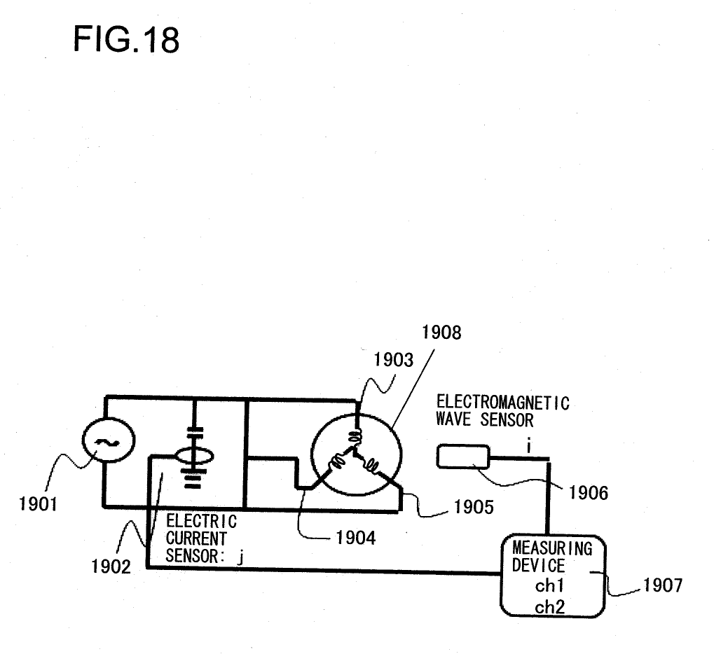

FIG. 18 shows in detail how a partial discharge having occurred in a rotating electric machine may be measured via sensors. As a rotating electric machine 1908 for a insulation diagnosis in the fourth embodiment, an AC motor generator is chosen as an example for explanation. The rotating electric machine 1908 is driven by a power source 1901 such as an inverter. A three-phase AC voltages provided from the power source 1901 are applied respectively to a U-phase terminal 1903, a V-phase terminal 1904 and a W-phase terminal 1905 in the rotating electric machine 1908. An electric current sensor j1902, constituted with a CT or a Hall element, detects an electric current flowing through the rotating electric machine 1908. An electromagnetic wave sensor i1906, installed within the rotating electric machine 1908, obtains a signal pertaining to a partial discharge occurring at an insulation defect area in the rotating electric machine 1908.

In addition to the partial discharge signal, noise is generated from the rotating electric machine 1908 and the power source 1901, and the two sensors j1902 and i1906, each obtain the partial discharge signal and the noise. A measuring device 1907, to which the signal having been obtained via the electric current sensor j1902 and the electromagnetic wave sensor i1906 are input through different input terminals ch1 and ch2 respectively, measures the partial discharge signal.

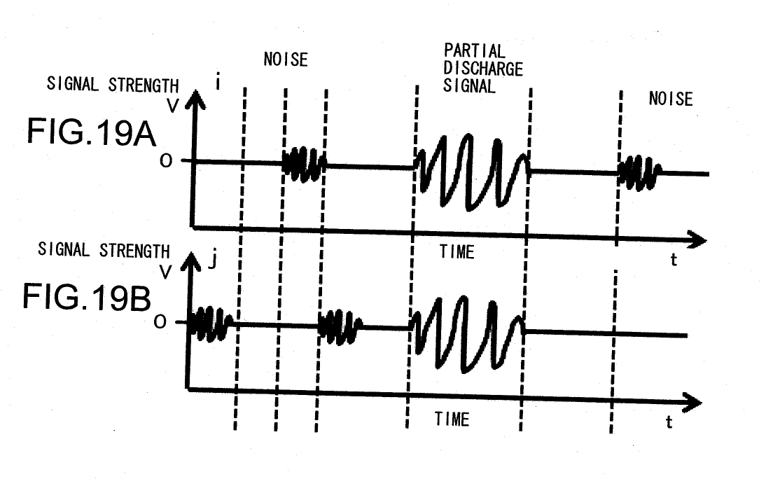

FIGS. 19A and 19B show how a noise separator (not shown, equivalent to the noise separator 0103 shown in FIG. 1) executes noise separation processing to separate the partial discharge signal from the noise. FIG. 19A shows the signal waveform of the signal measured via the electromagnetic wave sensor i1906, with the time t indicated along the horizontal axis and the signal strength V indicated along the vertical axis. FIG. 19B shows the signal waveform of the signal measured via the electric current sensor j1902, with the time t indicated along the horizontal axis and the signal strength V indicated along the vertical axis. A signal simultaneously detected at the electric current sensor j1902 and the electromagnetic wave sensor i1906 will be regarded to be a partial discharge signal by the noise separator. However, a signal detected only via either the electric current sensor j1902 or the electromagnetic wave sensor i1906 will be regarded as noise.

The partial discharge signal, having been separated from the noise through the noise separator, is provided to a spectrum converter (not shown, equivalent to the spectrum converter 0104 shown in FIG. 1) where it undergoes frequency analysis. In addition, an identifier (not shown, equivalent to the identifier 0105 shown in FIG. 1) identifies the insulation defect type based upon the frequency spectrum of the partial discharge signal. The insulation defect type can be identified through a method similar to that shown in FIG. 7. Next, the insulation defect type having been identified is indicated at an indicator (not shown, equivalent to the indicator 0106 shown in FIG. 1). The insulation diagnosis results may be indicated by adopting any of the display examples described in reference to the first embodiment.

As described above, the insulation diagnosis method in the fourth embodiment, in which the partial discharge signal is obtained via a plurality of sensors that detect different types of signals, achieves an advantage in that the noise separation processing is simplified, in addition to the advantages of the first embodiment described earlier.

### Fifth Embodiment

In the fifth embodiment described below, a partial discharge signal is obtained via a single sensor. In the fifth embodiment, a noise signal is obtained via a sensor and a threshold value equivalent to the maximum amplitude signal strength of the noise signal is set in advance. Then, any signal component exceeding the threshold value in a signal obtained via the sensor is extracted as a partial discharge signal and frequency analysis is executed for the extracted partial discharge signal so as to identify the insulation defect type. Since the sensor is the only element that differentiates the system configuration assumed in the fifth embodiment from the system configuration shown in FIG. 1, an illustration and explanation of the system configuration of the insulation diagnosis system in the fifth embodiment are omitted.

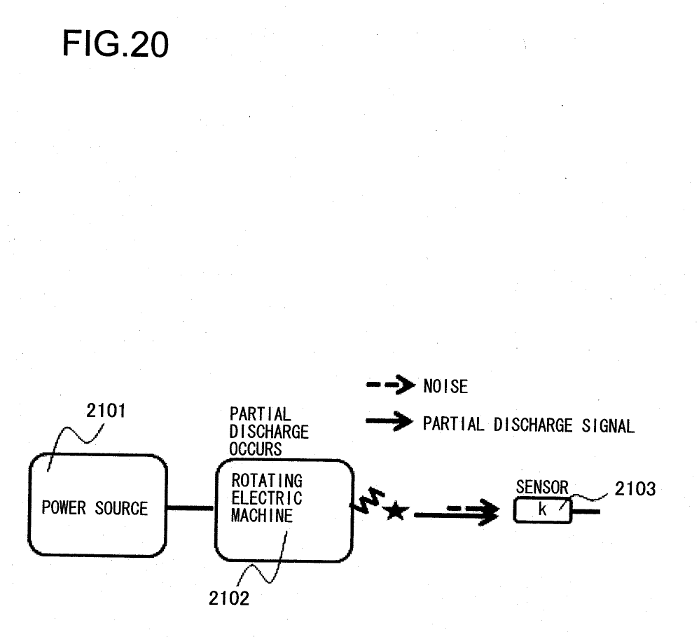

FIG. 20 shows in detail how the sensor measures a partial discharge having occurred in the rotating electric machine A rotating electric machine 2102 for an insulation diagnosis target may be an AC motor generator driven by a power source 2101 such as an inverter or may be a DC motor generator driven by a power source 2101 such as a converter. Electromagnetic waves attributable to a partial discharge occurring in the rotating electric machine 2102 and noise in the rotating electric machine 2102 are obtained via a single sensor k2103 installed within the rotating electric machine 2102.

The sensor k2103, installed within the rotating electric machine 2102, picks up electromagnetic waves attributable to a partial discharge having occurred in the rotating electric machine 2102 and noise occurring in the rotating electric machine 2602, and its output is supplied to a measuring device (equivalent to the measuring device 0102 shown in FIG. 1). It is to be noted that electromagnetic waves attributable to a partial discharge and noise may be also obtained via a sensor k2103 installed outside the rotating electric machine 2102. The sensor k2103 covers a frequency range in a DC through 100 MHz range over which separation of a partial discharge signal attributable to a partial discharge occurring in the rotating electric machine 2102 from the noise is considered to be difficult. FIG. 20 shows the noise (indicated by the dotted-line arrow in the figure) as well as partial discharge signals (indicated by the solid-line arrows in the figure) originating from the rotating electric machine 2102, with the sensor k2103 picking up both the partial discharge signal and the noise.

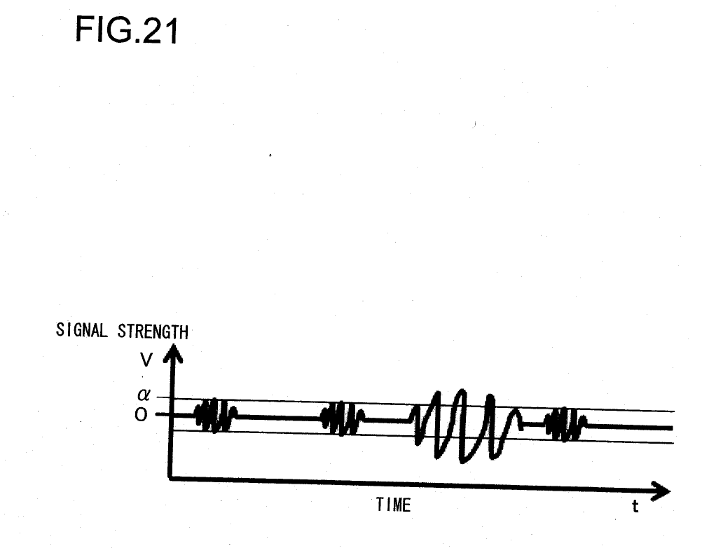

FIG. 21 shows separation processing executed by a noise separator (not shown, equivalent to the noise separator 0103 shown in FIG. 1) to separate the partial discharge signal from the noise. Noise is measured while the rotating electric machine 2102 is not running and the maximum amplitude signal strength of the noise signal is set as a threshold value α. Any signal component in which the maximum amplitude signal strength exceeds the threshold value in a signal obtained via the sensor k2103 while the rotating electric machine 2102 is driven by the power source 2101, will be identified as a signal attributable to a partial discharge having occurred at an insulation defect area in the rotating electric machine 2102, whereas the signal component with the maximum amplitude signal strength thereof equal to or less than the threshold value will be identified as noise.

The partial discharge signal, having been separated from the noise through the noise separator, is provided to a spectrum converter (not shown, equivalent to the spectrum converter 0104 shown in FIG. 1) where it undergoes frequency analysis. In addition, an identifier (not shown, equivalent to the identifier 0105 shown in FIG. 1) identifies the insulation defect type based upon the frequency spectrum of the partial discharge signal. The insulation defect type can be identified through a method similar to that shown in FIG. 7. Next, the insulation defect type having been identified is indicated at an indicator (not shown, equivalent to the indicator 0106 shown in FIG. 1). The insulation diagnosis results may be indicated by adopting any of the display examples described in reference to the first embodiment.

As described above, the insulation diagnosis method in the fifth embodiment, in which the partial discharge signal is obtained via a single sensor, achieves an advantage in that a simplified, inexpensive system is realized, in addition to the advantages of the first embodiment described earlier.

### Sixth Embodiment

While a threshold value is set based upon a noise signal obtained via a single sensor and a partial discharge signal and the noise are separated from each other in reference to the threshold value in the fifth embodiment described above, a partial discharge signal can be separated from cyclically occurring noise by measuring the noise in advance and removing the cyclical noise from a signal subsequently obtained via the single sensor.

The sixth embodiment achieved by adopting such a noise separation method is now described. It is to be noted that since the sensor is the only element that differentiates the system configuration assumed in the sixth embodiment from the system configuration shown in FIG. 1, an illustration and an explanation of the configuration of the insulation diagnosis system in the sixth embodiment are omitted. In addition, since the specific structural features assumed in the sensor that measures a partial discharge occurring in the rotating electric machine are similar to those shown in FIG. 20, its illustration and description are omitted.

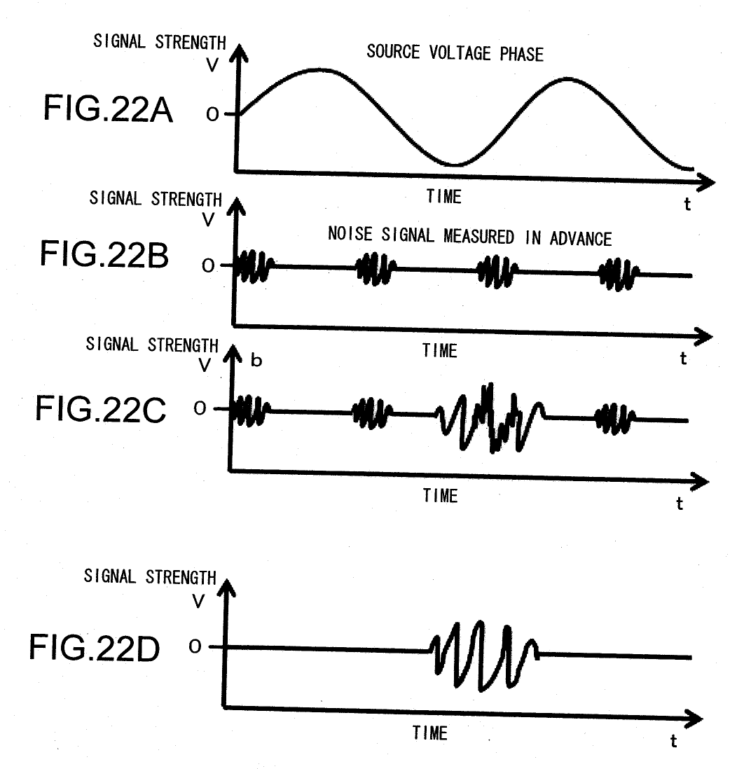

FIGS. 22A through 22D show noise separation processing executed by a noise separator (not shown, equivalent to the noise separator 0103 shown in FIG. 1) to separate the partial discharge signal from the noise. FIG. 22A shows the waveform of the voltage at a power source (equivalent to the power source 2101 shown in FIG. 20), whereas FIG. 22B shows the noise waveform. In addition, FIG. 22C shows the waveform of a signal containing the partial discharge signal and the noise.

The noise signal measured via the sensor and a measuring device is recorded in advance. Subsequently, a signal is measured via the sensor and the measuring device on a time scale of which time scale is same with the noise measurement. For instance, assuming a signal with a waveform such as that shown in FIG. 22C is obtained, the noise phase is aligned in the obtained signal waveform by referencing the phase of the power source voltage shown in FIG. 22A and the noise waveform shown in FIG. 22B is subtracted from the signal waveform shown in FIG. 22C having been obtained. If the signal having been obtained contains a partial discharge signal, the partial discharge signal alone is extracted as the remainder, as shown in FIG. 2D, and the partial discharge signal and the noise are thus successfully separated.

Since the insulation defect type can be identified based upon the extracted partial discharge signal and the identified insulation defect type can be indicated in much the same way as that described in reference to the fifth embodiment, a repeated explanation is not provided. Through the sixth embodiment, advantages similar to those of the fifth embodiment are achieved.

### Seventh Embodiment

In the seventh embodiment described below, the insulation defect type is identified by executing filter processing on a signal obtained via a sensor. In the seventh embodiment, a signal obtained via a single sensor is filtered through a plurality of filters bearing different frequency bands, each corresponding to a specific insulation defect type so as to identify the insulation defect type without having to execute signal frequency conversion processing.

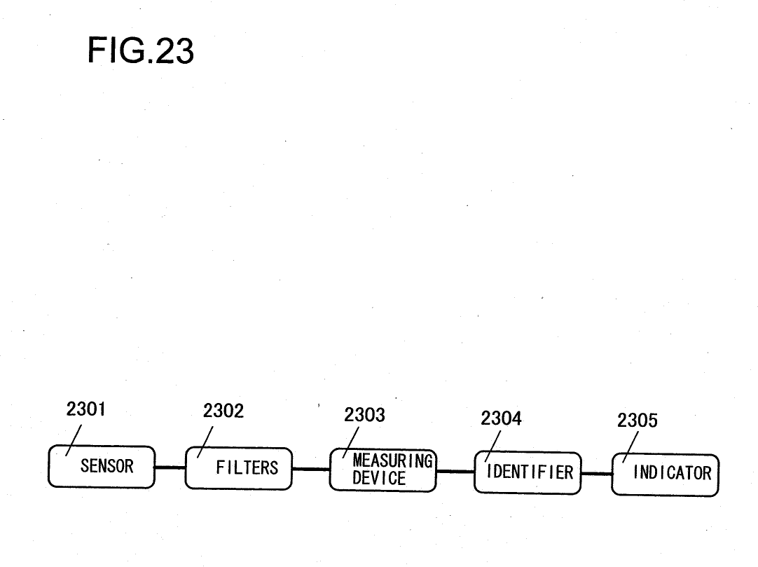

FIG. 23 shows the configuration of the insulation diagnosis system achieved in the seventh embodiment. The insulation diagnosis system comprises a sensor 2301, filters 2302 a measuring device 2303, an identifier 2304, an indicator 2305 and the like. Via the sensor 2301, a signal attributable to a partial discharge occurring in the rotating electric machine as insulation diagnosis target is obtained. Such a signal will contain noise occurring in an electric device installed around the rotating electric machine, such as an inverter power source used as the drive source for the rotating electric machine.

The filters 2302 include three different types of band pass filters bearing different frequency bands, each corresponding to a specific insulation defect type. As explained earlier, the maximum amplitude signal strength is registered in the frequency range of 50 through 70 MHz in the frequency spectrum of a partial discharge signal attributable to a wire-to-wire discharge defect, the maximum amplitude signal strength is registered over the frequency range of 2 through 20 MHz in the frequency spectrum of a partial discharge signal attributable to a void discharge defect and the maximum amplitude signal strength is registered over the frequency range of 30 through 50 MHz in the frequency spectrum of a partial discharge signal attributable to a surface discharge defect.

Accordingly, three types of band pass filters bearing frequency bands corresponding to the three insulation defect types, i.e., a band pass filter with a 50 to 70 MHz frequency range corresponding to the wire-to-wire discharge defect, a band pass filter with a 2 to 20 MHz frequency range corresponding to the void discharge defect and a band pass filter with a 30 to 50 MHz frequency range corresponding to the surface discharge defect, are used.

The measuring device 2303 measures the signal having passed through the three frequency ranges assumed at the filters 2302. The identifier 2304 identifies the insulation defect type based upon the maximum amplitude signal strength of the signal having passed through the three different frequency ranges. The insulation defect type thus identified is indicated via the indicator 2305.

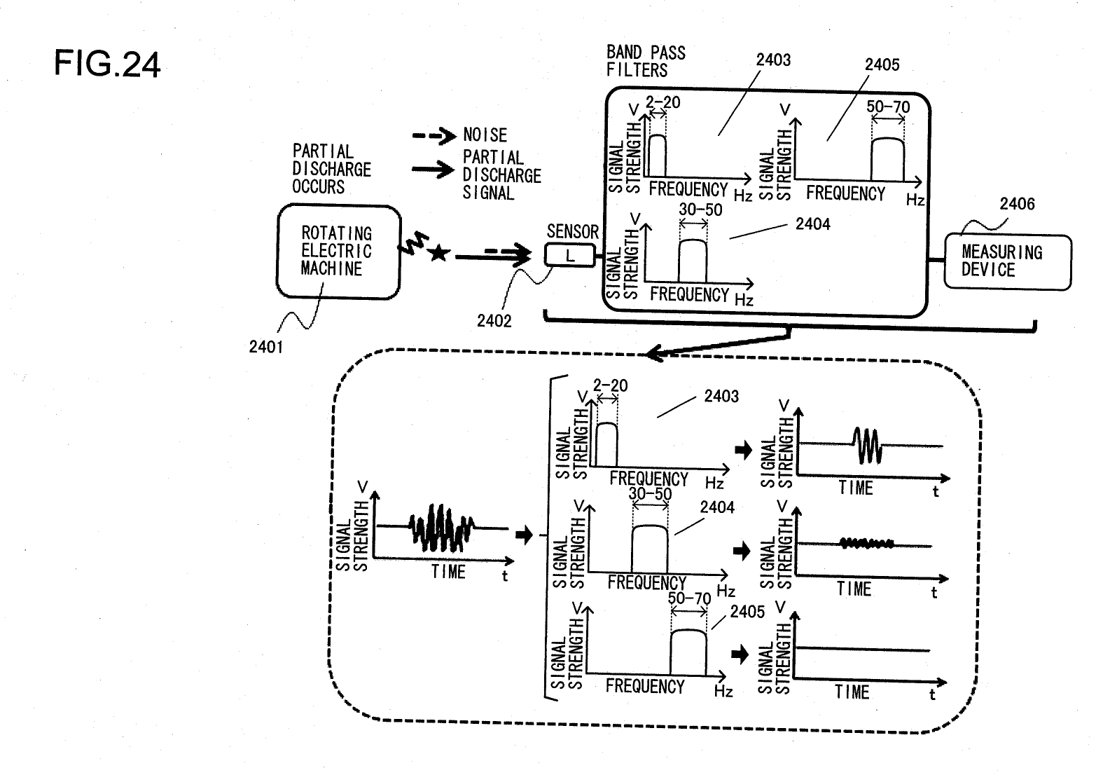

FIG. 24 shows in detail how a partial discharge, having occurred in a rotating electric machine, may be measured by a sensor. As in the various embodiments described earlier, a rotating electric machine 2401 as the insulation diagnosis target, which may be an AC motor generator or a DC motor generator, is driven by a power source (not shown). Electromagnetic waves attributable to a partial discharge occurring in the rotating electric machine 2401 and noise occurring in the rotating electric machine 2401 are both picked up via a single sensor L2402 installed within the rotating electric machine 2401

The sensor L2402 installed in the rotating electric machine 2401, picks up the electromagnetic waves attributable to a partial discharge and noise that occur in the rotating electric machine 2401 and its output is supplied to band pass filters 2403, 2404 and 2405. It is to be noted that electromagnetic waves attributable to a partial discharge and noise may be also obtained via a sensor L2402 installed outside the rotating electric machine 2401. The sensor L2402 covers the DC to 100 MHz frequency range, over which separation of a partial discharge signal from noise in the rotating electric machine 2401 is considered to be difficult in the related art. FIG. 24 shows the noise (indicated by the dotted-line arrow in the figure) as well as the partial discharge signal (indicated by the solid-line arrows in the figure) originating from the rotating electric machine 2401, with the sensor L2402 picking up both the partial discharge signal and the noise.

The band pass filters 2403, 2404 and 2405 respectively bear the 2 to 20 MHz frequency band, the 30 to 50 MHz frequency band and the 50 to 70 MHz frequency band. As shown in FIG. 24, signals corresponding to the three different frequency bands, i.e., the 2 to 20 MHz, the 30 to 50 MHz and the 50 to 70 MHz, are obtained by filtering the electromagnetic wave signal obtained via the sensor L2402 through the three types of band pass filters 2403, 2404 and 2405 and the signals thus obtained are each input to a specific channel at a measuring device 2406 for measurement.

The identifier 2304 (see FIG. 23) compares the maximum amplitude signal strength levels of the signals obtained through the individual channels at the measuring device 2406 and identifies the frequency band in which a signal with the maximum amplitude signal strength thereof exceeding the ordinary noise amplitude strength is present. It then recognizes the signal with the maximum amplitude signal strength as a partial discharge signal and identifies the insulation defect type in correspondence to the frequency band containing the particular signal.

In the example presented in FIG. 24, the signal with a maximum amplitude signal strength exceeding the noise amplitude strength is present in the 2 to 20 MHz frequency band while the 30 to 50 MHz frequency band contains a signal with an amplitude strength substantially same with that of the noise. Accordingly, the signal contained in the 2 to 20 MHz frequency band is recognized as the partial discharge signal and the partial discharge type is identified as a void discharge defect that typically manifests the maximum amplitude signal strength in the 2 to 20 MHz frequency band.

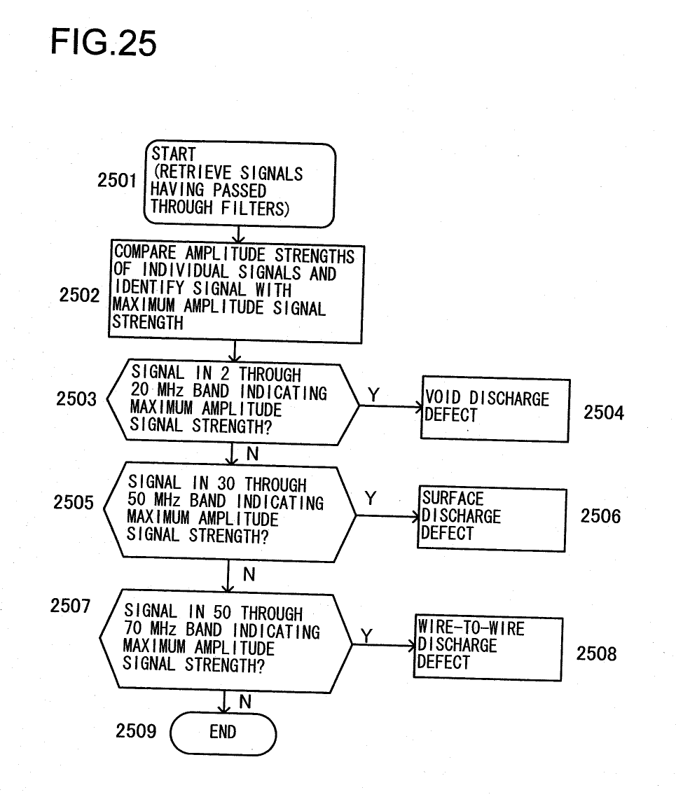

FIG. 25 presents a flowchart of the processing executed by the identifier 2304 based upon an insulation defect type identification program. In step 2501, three different types of signals obtained by filtering the sensor signal through the three band pass filters 2403 to 2405 are retrieved. In the following step 2502, the maximum amplitude signal strength levels of the signals in the three different frequency bands are compared and the signal with the highest maximum amplitude signal strength level is identified.

In step 2503, a decision is made as to whether or not the maximum amplitude signal strength is detected in the signal present in the 2 to 20 MHz frequency band, and if the signal with the maximum amplitude signal strength is present in the 2 to 20 MHz frequency band, the operation proceeds to step 2504 to determine that a partial discharge attributable to a void discharge defect has occurred. If, on the other hand, the signal with the maximum amplitude signal strength is not present in the 2 to 20 MHz frequency band, the operation proceeds to step 2505 to make a decision as to whether or not the maximum amplitude signal strength is detected in the signal present in the 30 to 50 MHz frequency band.

If the signal with the maximum amplitude signal strength is present in the 30 to 50 MHz frequency band, the operation proceeds to step 2506 to determine that a partial discharge attributable to a surface discharge defect has occurred. Moreover, if the signal with the maximum amplitude signal strength is not present in the 30 to 50 MHz frequency band, the operation proceeds to step 2507 to make a decision as to whether or not the maximum amplitude signal strength is detected in the signal present in the 50 to 70 MHz frequency band.

If the maximum amplitude signal strength is detected in the signal present in the 50 through 70 MHz frequency band, the partial discharge is determined to be attributable to a wire-to-wire discharge defect in step 2508. It is to be noted that if the signal with the maximum signal strength is not present in any of the frequency bands, the operation proceeds to step 2509 to terminate the identification processing upon determining that the insulation defect type cannot be identified.

Once the insulation defect type is identified by the identifier 2304, the insulation defect type having been identified is indicated via the indicator 2305 (see FIG. 23). The insulation diagnosis results can be indicated similarly to the display examples that having been described in reference to the first embodiment.

As described above, the insulation diagnosis system in the seventh embodiment, which does not require a noise separator or a spectrum converter, achieves an advantage in that an inexpensive and compact insulation diagnosis system can be realized, in addition to the advantages of the first embodiment having been explained earlier.

### Eighth Embodiment

In the eighth embodiment described below, the insulation defect position at which a partial discharge has occurred is estimated. As described earlier, electromagnetic waves attributable to a partial discharge are characterized in that the signal strength becomes gradually attenuated as the distance from the partial discharge location becomes larger. Accordingly, a plurality of partial discharge signal acquisition sensors are installed at constant intervals inside a rotating electric machine and the position at which a partial discharge has occurred, i.e., the insulation defect position, is estimated based upon the ratios of the signal strength levels of the signals obtained via the individual sensors.

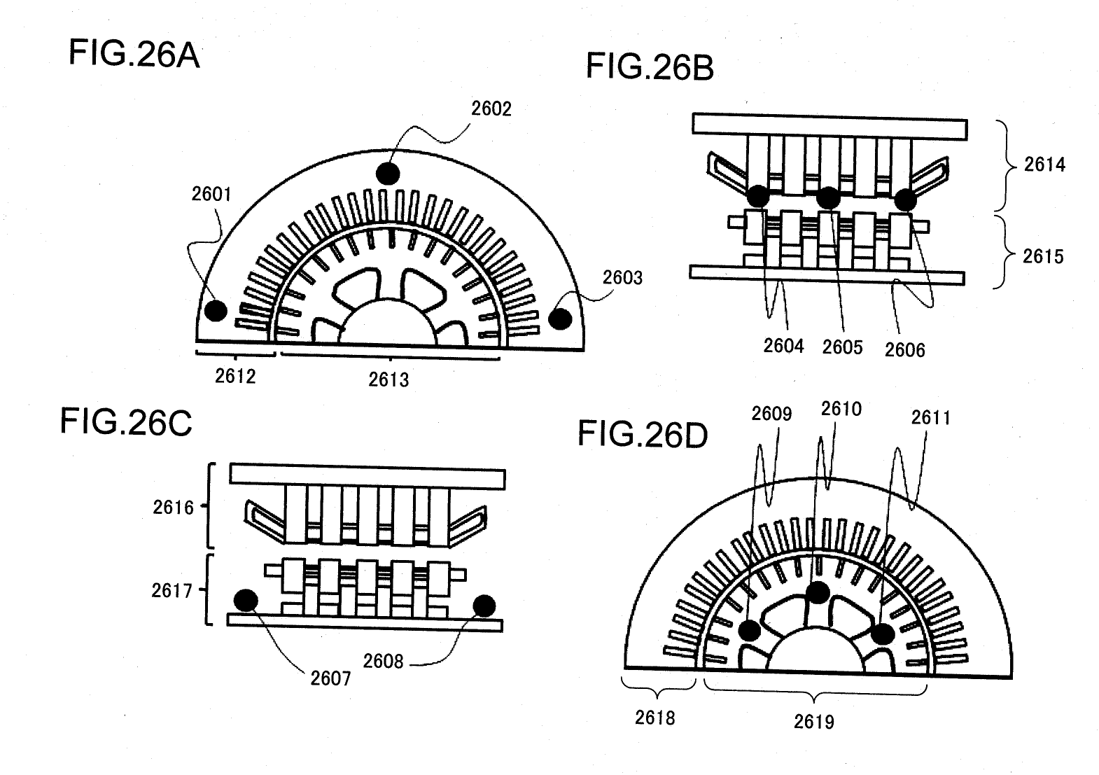

FIGS. 26A through 26D show how a plurality of partial discharge signal acquisition sensors may be installed in a rotating electric machine. FIG. 26A shows a lateral section (a plane perpendicular to the output shaft) of a rotating electric machine constituted with a stator 2612 and a rotor 1613, with three partial discharge signal acquisition sensors 2601, 2602 and 2603 installed over equal intervals along the lateral section inside the stator 2612. In addition, FIG. 26B shows a longitudinal section (a plane parallel to the output shaft) of a rotating electric machine constituted with a stator 2614 and a rotor 2615, with three partial discharge signal acquisition sensors 2604, 2605 and 2606 installed over equal intervals along the longitudinal section on the side where the stator 2614 is present.

FIG. 26C shows a longitudinal section of a rotating electric machine constituted with a stator 2616 and a rotor 2617, with two partial discharge signal acquisition sensors 2607 and 2608 installed at the rotor 2617, one at one of the two ends of the output shaft and the other at the other end of the output shaft. Furthermore, FIG. 26D shows a lateral section of a rotating electric machine constituted with a stator 2618 and a rotor 2619, with three partial discharge signal acquisition sensors 2609, 2610 and 2611 installed along the lateral section inside the stator 2619.

By installing a plurality of partial discharge signal acquisition sensors inside the rotating electric machine so as to identify the insulation defect type and estimate the insulation defect position based upon the signals provided by the sensors, a highly reliable rotating electric machine that allows electromagnetic waves, attributable to a partial discharge, to be picked up with high sensitivity and noise that is easily and accurately separated, can be provided. Furthermore, since defective products can be identified through the insulation diagnosis described above, conducted at the time of rotating electric machine final inspection performed prior to shipment, a highly reliable rotating electric machine can be manufactured and provided.

### Ninth Embodiment

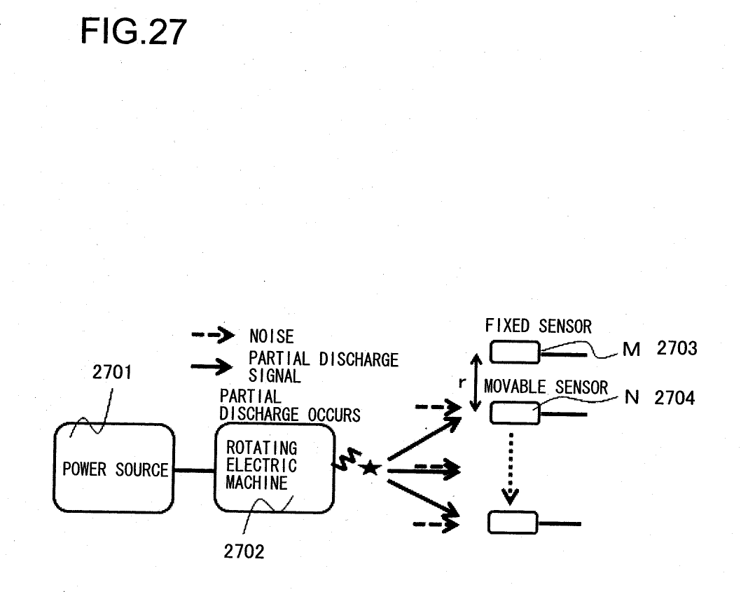

In the ninth embodiment described below, the insulation defect position is estimated in conjunction with a fixed sensor and a movable sensor. FIG. 27 shows a configuration that allows electromagnetic waves attributable to a partial discharge having occurred in a rotating electric machine 2702, which is driven by a power source 2701, to be picked up via a fixed sensor M2703 and a movable sensor N2704 each bearing a same characteristics. It is to be noted that since the system is configured similar to that achieved in the first embodiment described in reference to FIGS. 1 and 2, except for the structural features pertaining to the sensors M2703 and N2704, a repeated explanation is omitted.

Electromagnetic waves attributable to a partial discharge and noise occurring in the rotating electric machine 2702 are picked up via a fixed sensor M2703 and a movable sensor N2704 installed outside the rotating electric machine 2702, both used for purposes of partial discharge signal acquisition. The fixed sensor M2703 is fixed at a position in the vicinity of the rotating electric machine 2702. This means that the fixed sensor M2703 and the rotating electric machine 2702 assume fixed positions relative to each other. The movable sensor N2704, on the other hand, is allowed to move around the rotating electric machine 2702 as it is moved by a moving apparatus (not shown). In other words, the position of the movable sensor N2704 relative to the position of the rotating electric machine 2702 is variable.

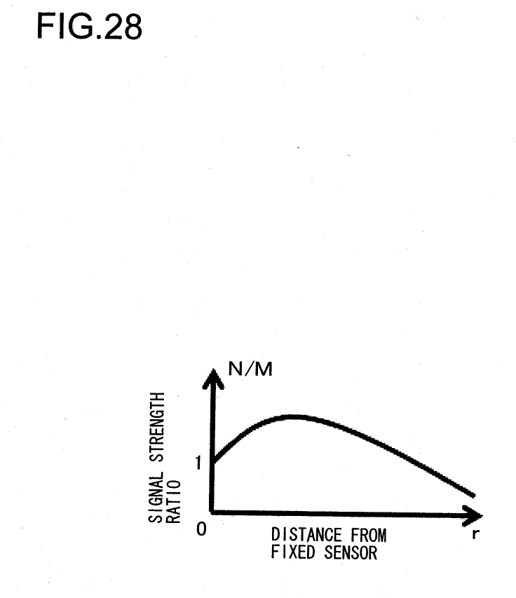

Data such as those presented in FIG. 28 are obtained by calculating the signal strength ratio of the signals obtained via the fixed sensor M2703 and the movable sensor N2704 (the ratio of the signal strength of the signal obtained via the movable sensor N2704 to the signal strength of the signal obtained via the fixed sensor M2703) with r representing the distance between the fixed sensor M2703 and the movable sensor N2704. Based upon the distance r, at which the strength ratio peaks, the position at which the partial discharge has occurred, i.e., the insulation defect position, can be estimated.

By obtaining a partial discharge signal via the fixed sensor M2703 and the movable sensor N2704 along an X axis and a Y axis passing through the rotating electric machine 2702, the insulation defect can be located at the point of intersection at which the insulation defect line detected along the X axis on the XY plane and the insulation defect line detected along the Y axis on the XY plane intersect each other.

The insulation defect position estimating method achieved in the ninth embodiment enables pinpoint repair of an area where the insulation performance is poor during maintenance work on a device such as a rotating electric machine, with compromised insulation performance, making it possible to reduce both the time and the cost of the repair.

It is to be noted that the embodiments and their variations described above may be adopted in any conceivable combination.

The above described embodiments are examples and various modifications can be made without departing from the scope of the invention.

What is claimed is:

1. An insulation diagnosis method comprising:
a measurement step of measuring a signal generated at a diagnosis target device;
a detection step of detecting a frequency or a frequency band manifesting a maximum amplitude signal strength is detected from the signal having been measured through the measurement step; and
an identification step of identifying an insulation defect type pertaining to an insulation defect having occurred in the diagnosis target device based upon the frequency or the frequency band manifesting the maximum amplitude signal strength having been detected through the detection step.

2. An insulation diagnosis method according to claim 1, wherein:
in the detection step, a frequency spectrum of the signal having been measured through the measurement step is detected and a frequency manifesting a maximum amplitude signal strength on the frequency spectrum is detected.

3. An insulation diagnosis method according to claim 1, wherein:
in the detection step, the signal having been measured through the measurement step is filtered through a plurality of band pass filters bearing different frequency band characteristics and a frequency band manifesting a maximum amplitude signal strength is detected by comparing strengths of signals which have passed the plurality of band pass filters.

4. An insulation diagnosis method according to claim 1, wherein:
in the measurement step, signals are measured via a plurality of sensors bearing different frequency band characteristics; and
in the detection step, a frequency range corresponding to a signal indicating a maximum amplitude signal strength is detected by comparing strengths of the signals having been measured via the plurality of sensors through the measurement step.

5. An insulation diagnosis method according to claim 1, wherein:
in the measurement step, signals generated from the diagnosis target device are measured via a plurality of sensors bearing same characteristics; and
an estimation step is executed in order to estimate an insulation defect position based upon a strength ratio of strengths of the signals having been measured via the plurality of sensors bearing same characteristics.

6. An insulation diagnosis method according to claim 5, wherein:
the plurality of sensors comprise a fixed sensor assuming a fixed position relative to the diagnosis target device and a movable sensor assuming a variable position relative to the diagnosis target device; and
in the estimation step, the insulation defect position is estimated based upon a strength ratio of strengths of signals measured via the fixed sensor and the movable sensor.

7. An insulation diagnosis method according to claim 5, wherein:
in the measurement step, the strengths of the signals having been measured via the plurality of sensors bearing same characteristics are compared and a partial discharge signal attributable to an insulation defect and noise are separated from each other based upon comparison results.

8. An insulation diagnosis method according to claim 1, wherein:
in the measurement step, a partial discharge signal attributable to an insulation defect is extracted by taking a difference between the signal having been measured and noise having been measured in advance.

9. An insulation diagnosis method according to claim 1, wherein:
in the measurement step, signals generated from the measurement target device are measured via a first sensor and a second sensor that measure different types of signals and a signal detected simultaneously via the first sensor and the second sensor is extracted as a partial discharge signal attributable to an insulation defect.

10. An insulation diagnosis method according to claim 1, wherein:
in the measurement step, a signal component in the signal having been measured, which exceeds a preselected threshold value, is extracted as a partial discharge signal attributable to an insulation defect.

11. An insulation diagnosis method according to claim 1, wherein:
in the identification step, a wire-to-wire discharge defect, a void discharge defect or a surface discharge defect, occurring in a rotating electric machine designated as the diagnosis target device, is identified.

12. An insulation diagnosis method according to claim 11, wherein:
in the identification step, an insulation defect having occurred is identified as the wire-to-wire discharge defect if the frequency manifesting the maximum amplitude signal strength is in a range of 50 through 70 MHz, as the void discharge defect if the frequency manifesting the maximum amplitude signal strength is in a range of 2 through 20 MHz and as the surface discharge defect if the frequency manifesting the maximum amplitude signal strength is in a range of 30 through 50 MHz.

13. An insulation diagnosis method according to claim 11, wherein:
in the measurement step, a signal generated from the rotating electric machine is measured via a sensor installed at the rotating electric machine.

14. A rotating electric machine for which insulation diagnosis is executed by adopting an insulation diagnosis method according to claim 1.

15. An insulation diagnosis system, comprising:
a detection unit that detects a frequency or a frequency range manifesting a maximum amplitude signal strength based upon a signal provided by a measuring device that measures a signal generated from an insulation diagnosis target device; and
an identification unit that identifies an insulation defect type pertaining to an insulation defect having occurred in the diagnosis target device based upon the frequency or the frequency range manifesting the maximum amplitude signal strength having been detected by the detection unit.

16. An insulation diagnosis system according to claim 15, wherein:
the detection unit detects a frequency spectrum of the signal having been measured by the measuring device and detects a frequency manifesting a maximum amplitude signal strength on the frequency spectrum.

17. An insulation diagnosis system according to claim 15, wherein:
the detection unit filters the signal having been measured by the measuring device through a plurality of band pass filters bearing different frequency band characteristics and detects a frequency band manifesting a maximum amplitude signal strength.

18. An insulation diagnosis system according to claim 15, wherein:
the measuring device measures signals via a plurality of sensors bearing different frequency band characteristics; and
the detection unit detects a frequency range corresponding to a signal indicating a maximum amplitude signal strength among the signals having been measured via the plurality of sensors.
